(19) United States
(12) Patent Application Publication
(10) Pub. No.: US 2024/0224569 A1
(43) Pub. Date: Jul. 4, 2024

(54) LIGHT EMITTING DISPLAY DEVICE

(71) Applicant: LG Display Co., Ltd., Seoul (KR)

(72) Inventors: Ki Min LIM, Paju-si (KR); Seung Kwang ROH, Paju-si (KR); Woo Chul CHOI, Paju-si (KR); Sang Kyoung MOON, Paju-si (KR); Dong Il CHOI, Paju-si (KR)

(73) Assignee: LG Display Co., Ltd., Seoul (KR)

(21) Appl. No.: 18/540,402

(22) Filed: Dec. 14, 2023

(30) Foreign Application Priority Data
Dec. 28, 2022 (KR) 10-2022-0187324

(51) Int. Cl. H10K 50/13; H10K 50/805; H10K 59/122; H10K 59/35

(52) U.S. Cl. CPC H10K 50/13; H10K 50/805; H10K 59/122; H10K 59/351; H10K 59/353

(57) ABSTRACT

A light emitting display device can include a first area including a first light emitting portion to emit a first color of light, a second light emitting portion to emit a second color of light, and a third light emitting portion to emit a third color of light; and a second area adjacent to the first area, the second area including a fourth light emitting portion to emit the first color of light, a fifth light emitting portion to emit the second color of light, a sixth light emitting portion to emit the third color of light, and a seventh light emitting portion to emit white light. Also, each of the first, second, third, fourth, fifth, sixth and seventh light emitting portions includes a plurality of stacks, and a light emitting layer in at least one of the plurality of stacks is continuous and extends into the seventh light emitting portion from one of the other light emitting portions.

### CROSS REFERENCE TO RELATED APPLICATION

This application claims priority under 35 U.S.C. § 119(a) to Korean Patent Application No. 10-2022-0187324, filed in the Republic of Korea on Dec. 28, 2022, which is hereby incorporated by reference into the present application as if fully set forth herein.

### BACKGROUND

### Field of the Invention

The present disclosure relates to a display device, and more particularly to a light emitting display device capable of achieving high resolution and improving color efficiency by changing the stack structure and the arrangement of light emitting portions.

### Discussion of the Related Art

With the advent of the information age, displays capable of visually expressing electrical information signals have been rapidly developed. Correspondingly, various display devices have been developed, which have excellent performance and improved characteristics, such as slimness, light weight, and low power consumption.

Among the display devices, a light emitting display device having a light emitting element in a display panel has been considered as a competitive application in order to reduce a size the device and provide a vivid color display without needing a separate light source (e.g., no backlight unit).

The light emitting element includes an anode and a cathode opposite each other and a light emitting portion provided between the anode and the cathode. In addition, the light emitting element can include a common layer that transports holes and electrons to the light emitting portion.

In addition, the light emitting element can be formed to have a plurality of stacks in order to improve efficiency thereof.

### SUMMARY OF THE DISCLOSURE

In a structure in which a plurality of stacks are provided for each color in a light emitting display device, each color light emitting portion needs a fine deposition mask having an aperture limited by the size of the light emitting portion in the state in which the number of the fine deposition masks is equal or greater than the number of the stacks.

In addition, for expressing different colors, the number of fine deposition masks needed for the light emitting portions can increase and cause the manufacturing process to be more complicated and expensive.

The present disclosure provides a light emitting display device configured such that each of the color light emitting portions includes a plurality of stacks in order to improve color efficiency, and the color light emitting portions are disposed adjacent to a white light emitting portion, in order to reduce the number of deposition masks.

A light emitting display device according to the present disclosure can be configured such that a white light emitting portion is provided between color light emitting portions adjacent to each other, in order to improve white efficiency and drive the white light emitting portion under similar conditions as the color light emitting portions.

Also, in the light emitting display device according to the present disclosure, color light emitting layers of the color light emitting portions are also formed in the white light emitting portion, so that it is not necessary to provide a separate deposition mask to form the white light emitting portion and the white light emitting portion can be formed using deposition masks that are used for forming the color light emitting portions. In other words, it is possible to simultaneously form light emitting layers of the white light emitting portion and light emitting layers of the color light emitting portions using an aperture of the same mask, in order to implement high resolution without the addition of separate equipment.

A light emitting display device according to an embodiment of the present disclosure includes a first area on a substrate, the first area including a first light emitting portion to emit a first color of light, a second light emitting portion to emit a second color of light, and a third light emitting portion to emit a third color of light, and a second area disposed on the substrate to be adjacent to the first area, the second area including a fourth light emitting portion to emit the first color of light, a fifth light emitting portion to emit the second color of light, a sixth light emitting portion to emit the third color of light, and a seventh light emitting portion to emit white light. Each of the first to seventh light emitting portions can include a plurality of stacks, and a light emitting layer in at least one of the stacks among the fourth to sixth light emitting portions can be continuous with the seventh light emitting portion.

It is to be understood that both the foregoing general description and the following detailed description of the present disclosure are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain principles of the invention. In the drawings:

FIG. 1 is a block diagram schematically showing a light emitting display device according to an embodiment of the present disclosure;

FIG. 2 is a plan view showing a light emitting display device according to an embodiment of the present disclosure;

FIG. 3 is a sectional view taken along line I-I′ of FIG. 2 according to an embodiment of the present disclosure;

FIG. 4 is a sectional view taken along line II-II′ of FIG. 2 according to an embodiment of the present disclosure;

FIG. 5 is a sectional view taken along line III-III′ of FIG. 2 according to an embodiment of the present disclosure;

FIG. 6 is a sectional view taken along line IV-IV′ of FIG. 2 according to an embodiment of the present disclosure;

FIG. 7 is a sectional view taken along line V-V′ of FIG. 2 according to an embodiment of the present disclosure;

FIG. 8 is a plan view showing a light emitting display device according to another embodiment of the present disclosure;

FIG. 9 is a sectional view taken along line VI-VI′ of FIG. 8 according to an embodiment of the present disclosure;

FIG. 10 is a sectional view taken along line VII-VII′ of FIG. 8 according to an embodiment of the present disclosure;

FIG. 11 is a plan view showing a light emitting display device according to another embodiment of the present disclosure;

FIG. 12 is a plan view showing a light emitting display device according to another embodiment of the present disclosure;

FIG. 13 is a sectional view showing a light emitting display device according to an embodiment of the present disclosure;

FIG. 14 is a plan view showing a method of manufacturing the light emitting display device of FIG. 13 according to an embodiment of the present disclosure;

FIG. 15 is a sectional view showing a light emitting display device according to an embodiment of the present disclosure;

FIG. 16 is a plan view showing a method of manufacturing the light emitting display device of FIG. 15 according to an embodiment of the present disclosure;

FIGS. 17 to 19 are graphs showing individual stack efficiency and overall stack efficiency of a blue light emitting portion, a green light emitting portion, and a red light emitting portion of the light emitting display device according to an embodiment of the present disclosure;

FIG. 20 is a graph showing a light emission spectrum of a white light emitting portion of the light emitting display device according to an embodiment of the present disclosure; and

FIG. 21 is a graph showing I-V characteristics of blue, green, red, and white light emitting portions of the light emitting display device according to an embodiment of the present disclosure.

### DETAILED DESCRIPTION OF THE EMBODIMENTS

Reference will now be made in detail to example embodiments of the present disclosure, examples of which are illustrated in the accompanying drawings. Wherever possible, the same reference numbers will be used throughout the drawings to refer to the same or like parts, unless otherwise specified.

Advantages and features of the present disclosure, and a method of achieving the advantages and features will become apparent with reference to the example embodiments described herein in detail together with the accompanying drawings. The present disclosure should not be construed as limited to the example embodiments as disclosed below, and can be embodied in various different forms. Thus, these example embodiments are set forth only to make the present disclosure sufficiently complete, and to assist those skilled in the art to fully understand the scope of the present disclosure. The protected scope of the present disclosure is defined by the claims and their equivalents.

In the following description of the present disclosure, where the detailed description of the relevant known steps, elements, functions, technologies, and configurations can unnecessarily obscure an important point of the present disclosure, a detailed description of such steps, elements, functions, technologies, and configurations may be omitted. In addition, the names of elements used in the following description are selected in consideration of clarity of description of the specification, and can differ from the names of elements of actual products. Furthermore, in the following detailed description of the present disclosure, numerous specific details are set forth in order to provide a sufficiently thorough understanding of the present disclosure. However, it will be understood that the present disclosure can be practiced without these specific details. In other instances, known methods, procedures, components, and circuits have not been described in detail so as not to unnecessarily obscure aspects of the present disclosure.

The shapes, sizes, ratios, angles, numbers, and the like, which are illustrated in the drawings to describe various example embodiments of the present disclosure are merely given by way of example. The disclosure is not limited to the illustrations in the drawings.

In the present specification, where terms such as “including,” “having,” “comprising,” and the like are used, one or more components can be added, unless the term, such as “only,” is used. As used herein, the term “and/or” includes a single associated listed item and any and all of the combinations of two or more of the associated listed items.

An expression such as “at least one of” when preceding a list of elements may modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In construing a component or numerical value, the component or the numerical value is to be construed as including an error or tolerance range even where no explicit description of such an error or tolerance range is provided.

In describing the various example embodiments of the present disclosure, where the positional relationship between two elements is described using terms, such as “on,” “above,” “under” and “next to,” at least one intervening element can be present between the two elements, unless “immediate(ly)” or “direct(ly)” or “close(ly) is used. It will be understood that when an element or layer is referred to as being “connected to,” or “coupled to” another element or layer, it can be directly connected to or coupled to the other element or layer, or one or more intervening elements or layers can be present.

In describing the various example embodiments of the present disclosure, when terms such as “after,” “subsequently,” “next,” and “before,” are used to describe the temporal relationship between two events, another event can occur therebetween, unless a more limiting term, such as “just,” “immediate(ly),” or “directly” is used.

In describing the various example embodiments of the present disclosure, terms such as “first” and “second” can be used to describe a variety of components. These terms aim to distinguish the same or similar components from one another and do not limit the components. Accordingly, throughout the specification, a “first” component can be the same as a “second” component within the technical concept of the present disclosure, unless specifically mentioned otherwise.

Features of various embodiments of the present disclosure can be partially or overall coupled to or combined with each other, and can be variously inter-operated with each other and driven technically as those skilled in the art may sufficiently understand. The embodiments of the present disclosure can be carried out independently from each other, or can be carried out together in a co-dependent relationship.

As used herein, the term “doped” layer refers to a layer including a first material and a second material (for example, n-type and p-type materials, or organic and inorganic substances) having physical properties different from the first material. Apart from the differences in properties, the first and second materials can also differ in terms of their amounts in the doped layer. For example, the host material can be a major component while the dopant material can be a minor component. The first material accounts for most of the weight of the doped layer. The second material can be added in an amount less than 30% by weight, based on a total weight of the first material in the doped layer. A “doped” layer can be a layer that is used to distinguish a host material from a dopant material of a certain layer, in consideration of the weight ratio. For example, if all of the materials constituting a certain layer are organic materials, at least one of the materials constituting the layer is n-type and the other is p-type, when the n-type material is present in an amount of less than 30 wt %, or when the p-type material is present in an amount of less than 30 wt %, the layer is considered to be a “doped” layer.

Also, the term “undoped” refers to layers that are not “doped.” For example, a layer can be an “undoped” layer when the layer contains a single material or a mixture including materials having the same properties as each other. For example, if at least one of the materials constituting a certain layer is p-type and none of the materials constituting the layer are n-type, the layer is considered to be an “undoped” layer. For example, if at least one of the materials constituting a layer is an organic material and none of the materials constituting the layer are inorganic materials, the layer is considered to be an “undoped” layer.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In this present disclosure, an electroluminescence (EL) spectrum can be calculated by multiplying (a) a photoluminescence (PL) spectrum, which applies the inherent characteristics of an emissive material such as a dopant material or a host material included in an organic emission layer, by (b) an outcoupling or emittance spectrum curve, which is determined by the structure and optical characteristics of an organic light-emitting element including the thicknesses of organic layers such as, for example, an electron transport layer.

Hereinafter, example embodiments of the present disclosure will be described in detail with reference to the accompanying drawings. In adding reference numerals to elements of each of the drawings, although the same elements are illustrated in other drawings, like reference numerals can refer to like elements. Also, for convenience of description, a scale in which each of elements is illustrated in the accompanying drawings can differ from an actual scale. Thus, the illustrated elements are not limited to the specific scale in which they are illustrated in the drawings.

Hereinafter, a light emitting display device according to the present disclosure and a method of manufacturing the same will be described with reference to the accompanying drawings.

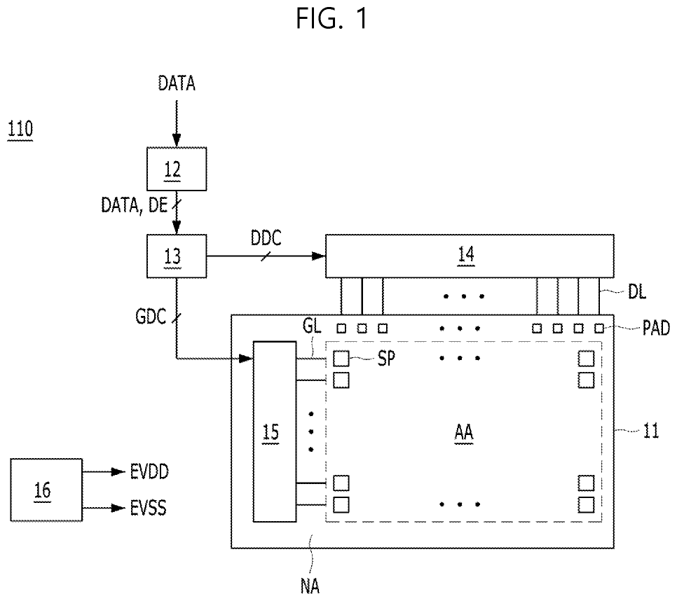

FIG. 1 is a block diagram schematically showing a light emitting display device according to the present disclosure.

As shown in FIG. 1, the light emitting display device according to an embodiment of the present disclosure can include a display panel 11, an image processing unit 12, a timing controller 13, a data driving unit 14 (e.g., a data driver), a scan driving unit 15 (e.g., a gate driver or a scan driver), and a power supply unit 16.

The display panel 11 can display an image according to a data signal DATA supplied from the data driving unit 14, a scan signal supplied from the scan driving unit 15, and power supplied from the power supply unit 16.

The display panel 11 can include a subpixel SP disposed at each of intersections between a plurality of gate lines GL and a plurality of data line DL. The structure of the subpixel SP can be variously changed depending on kind of the light emitting display device.

For example, the subpixel SP can be formed as a top emission type subpixel, a bottom emission type subpixel, or a dual emission type subpixel depending on structure thereof. The subpixel SP means a unit pixel having a specific kind of color filter or a unit pixel having a light emitting portion configured to emit an assigned color of light without a color filter.

For example, subpixels SP can include a red subpixel, a green subpixel, and a blue subpixel. Alternatively, the subpixels SP can include a red subpixel, a blue subpixel, a white subpixel, and a green subpixel. The subpixels SP can have one or more different light emission areas depending on light emission characteristics thereof. For example, the blue subpixel, the red subpixel and the green subpixel can have several of different light emission areas.

In the embodiment of the present disclosure, the subpixel includes a first light emitting portion, a second light emitting portion, and a third light emitting portion that emit different colors of light, and a white light emitting portion. Emission colors, disposition type, and disposition sequence of the light emitting portions can be variously configured depending on light emission characteristics, the lifespan of the element, and the specifications of the device, and the present disclosure is not limited thereto.

The display panel 11 can be divided into an active area AA in which the subpixels SP are disposed to display an image and a non-active area NA around the active area AA. The scan driving unit 15 can be mounted in the non-active area NA of the display panel 11. In addition, a pad unit PAD including a pad electrode PD can be provided in the non-active area NA. The one or more thin film transistor TFTs may be arranged as a layered structure on the substrate 100. On top of the one or more thin film transistor TFTs there is the layered structure of the light emitting element 120 to 170 (BE1, BE2, GE1, GE2, RE1, RE2, and WE). The light emitting elements 120 to 170 (BE1, BE2, GE1, GE2, RE1, RE2, and WE) are covered and protected by the encapsulation layer disposed on top of the light emitting elements 120 to 170 (BE1, BE2, GE1, GE2, RE1, RE2, and WE).

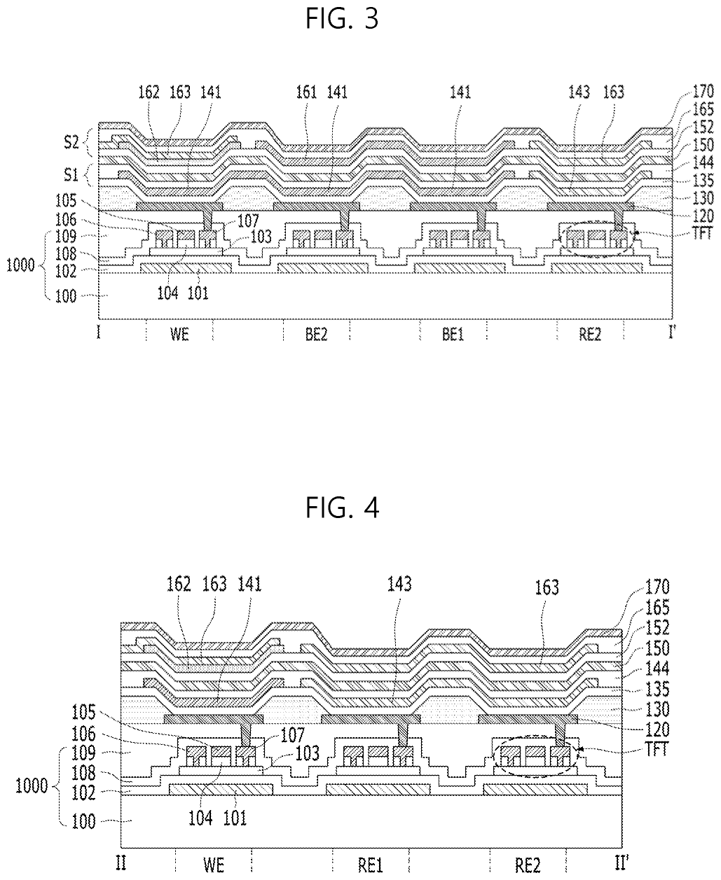

The display panel 11 includes a substrate 100 (e.g., see FIGS. 3 to 7), a thin film transistor TFT (e.g., see FIGS. 3 to 7) provided on the substrate 100, a light emitting element 120 to 170 (BE1, BE2, GE1, GE2, RE1, RE2, and WE) (e.g., see FIGS. 3 to 7), and an encapsulation layer configured to cover the thin film transistor TFT and the light emitting element.

The image processing unit 12 can output the data signal DATA supplied from the outside and a data enable signal DE. The image processing unit 12 can output at least one of a vertical synchronization signal, a horizontal synchronization signal, and a clock signal, in addition to the data enable signal DE. These signals are omitted for convenience of description.

The timing controller 13 can receive a driving signal and the data signal DATA from the image processing unit 12. The driving signal can include the data enable signal DE. Alternatively, the driving signal can include the vertical synchronization signal, the horizontal synchronization signal, and the clock signal. The timing controller 13 can output a data timing control signal DDC for controlling operation timing of the data driving unit 14 and a gate timing control signal GDC for controlling operation timing of the scan driving unit 15 based on the driving signal.

The data driving unit 14 can sample, latch, and convert the data signal DATA supplied from the timing controller 13 into a gamma reference voltage and can output the gamma reference voltage in response to the data timing control signal DDC supplied from the timing controller 13.

The data driving unit 14 can output the data signal DATA through the data lines DL. The data driving unit 14 can be implemented in the form of an integrated circuit (IC). For example, the data driving unit 14 can be electrically connected to the pad electrode PD disposed in the non-active area NA of the display panel 11 via a flexible circuit film.

The scan driving unit 15 can output the scan signal in response to the gate timing control signal GDC supplied form the timing controller 13. The scan driving unit 15 can output the scan signal through the gate lines GL. The scan driving unit 15 can be implemented in the form of an integrated circuit (IC) or in the form of a gate in panel (GIP) in the display panel 11.

The power supply unit 16 can output a high-potential voltage and a low-potential voltage for driving the display panel 11. The power supply unit 16 can supply the high-potential voltage to the display panel 11 via a first power line EVDD (e.g., a driving power line or a pixel power line), and can supply the low-potential voltage to the display panel 11 via a second power line EVSS (e.g., an auxiliary power line or a common power line).

The display panel 11 can be divided into the active area AA and the non-active area NA, and can include the plurality of subpixels SP defined by the gate lines GL and the data lines DL intersecting each other in a matrix form on the substrate 100 in the active area AA.

The subpixels SP can include subpixels configured to emit at least two of red light, green light, blue light, yellow light, magenta light, and cyan light and a white subpixel, but embodiments are not limited thereto. In addition, each of the plurality of subpixels SP can have a specific kind of color filter or can emit an assigned color of light without a color filter. However, the present disclosure is not limited thereto, and emission colors, disposition type, and disposition sequence of the subpixels SP can be variously configured depending on light emission characteristics, the lifespan of the element, and the specifications of the device.

Hereinafter, features of the present disclosure based on the structure of a light emitting element provided in each light emitting portion will be described with reference to a plan view schematically showing the light emitting display device according to the present disclosure.

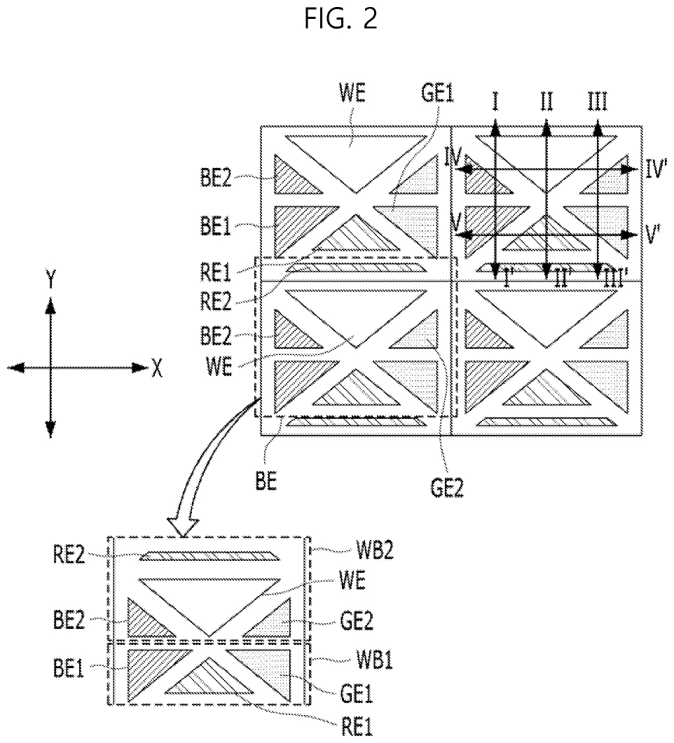

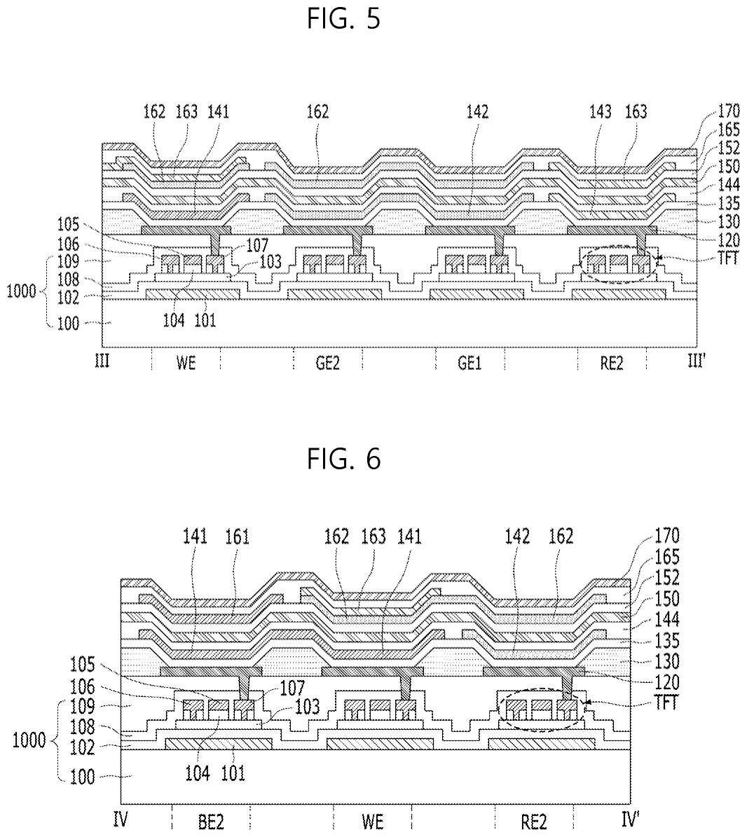

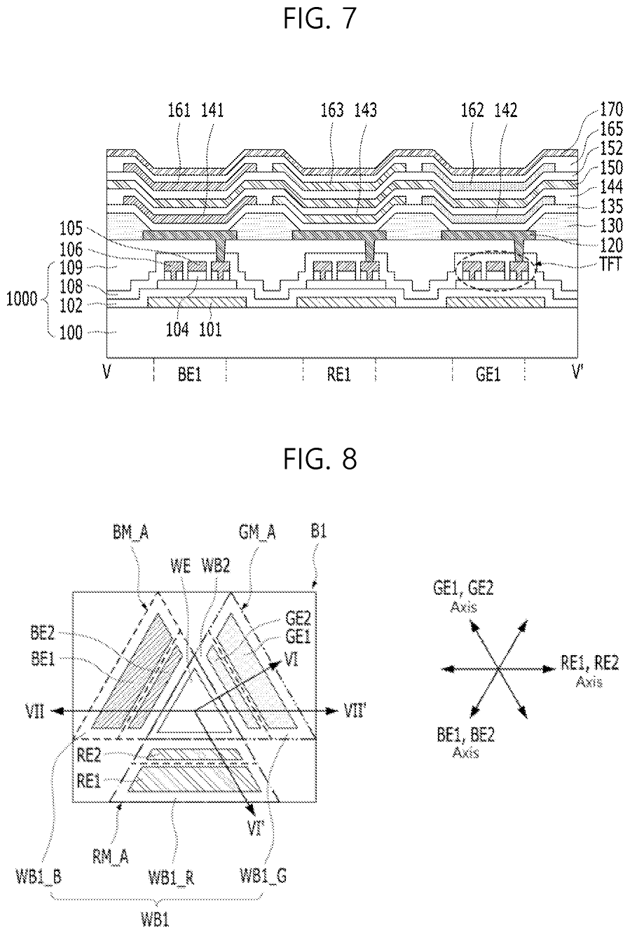

FIG. 2 is a plan view showing a light emitting display device according to a first embodiment of the present disclosure. FIG. 3 is a sectional view taken along line I-I′ of FIG. 2 according to an embodiment of the present disclosure. FIG. 4 is a sectional view taken along line II-II′ of FIG. 2 according to an embodiment of the present disclosure. FIG. 5 is a sectional view taken along line III-III′ of FIG. 2 according to an embodiment of the present disclosure. FIG. 6 is a sectional view taken along line IV-IV′ of FIG. 2 according to an embodiment of the present disclosure. FIG. 7 is a sectional view taken along line V-V′ of FIG. 2 according to an embodiment of the present disclosure.

As shown in FIG. 2, the light emitting display device according to the first embodiment of the present disclosure includes a first area WB1 and a second area WB2 disposed adjacent to each other on a thin film transistor array board or array 1000.

The second area WB2 is different from the first area WB1 in that a white light emitting portion WE is further provided. For example, a white light emitting portion WE is present in the second area WB2, but the first area WB1 does not include a white light emitting portion WE. The first area WB1 includes a first blue light emitting portion BE configured to emit blue light, a first green light emitting portion GE1 configured to emit green light, and a first red light emitting portion RE1 configured to emit red light. The second area WB2 includes a second blue light emitting portion BE2 configured to emit blue light, a second green light emitting portion GE2 configured to emit green light, a second red light emitting portion RE2 configured to emit red light, and a white light emitting portion WE configured to emit white light.

The white light emitting portion WE can be disposed in the center of the second area WB2. The second blue light emitting portion BE2, the second green light emitting portion GE2, and the second red light emitting portion RE2 can be disposed to surround the white light emitting portion WE. Consequently, a light emitting layer of the white light emitting portion WE can be formed using light emitting layers of at least one of the second blue light emitting portion BE2, the second green light emitting portion GE2, and the second red light emitting portion RE2. In other words, the white light emitting portion WE is surrounded by at least one blue light emitting portion, at least one green light emitting portion and at least one red light emitting portion. That is, an aperture of a deposition mask for forming the light emitting layers of the second blue light emitting portion BE2, the second green light emitting portion GE2, and the second red light emitting portion RE2 around the white light emitting portion WE can extend to the white light emitting portion WE to form the light emitting layer of the white light emitting portion WE without the addition of another deposition mask for forming the light emitting layer of the white light emitting portion WE.

In the light emitting display device according to the present disclosure, the first blue light emitting portion BE1 of the first area WB1 and the second blue light emitting portion BE2 of the second area WB2 can be disposed adjacent to each other side by side, in this way, the first and second blue light emitting portions BE1 and BE2 can be formed using an aperture of one deposition mask together with the white light emitting portion WE. In the same manner, the first green light emitting portion GE1 of the first area WB1 and the second green light emitting portion GE2 of the second area WB2 can be disposed adjacent to each other side by side, whereby the first and second green light emitting portions GE1 and GE2 can be formed using an aperture of one deposition mask together with the white light emitting portion WE. The first red light emitting portion RE1 of the first area WB1 and the second red light emitting portion RE2 of the second area WB2 can be disposed adjacent to each other side by side, whereby the first and second red light emitting portions RE1 and RE2 can be formed using an aperture of one deposition mask together with the white light emitting portion WE.

As shown in FIG. 2, the first blue light emitting portion BE1 of the first area WB1 and the second blue light emitting portion BE2 of the second area WB2 can face each other at a boundary between the first area WB1 and the second area WB2. The first green light emitting portion GE1 of the first area WB1 and the second green light emitting portion GE2 of the second area WB2 can face each other at a boundary between the first area WB1 and the second area WB2. The first red light emitting portion RE1 of the first area WB1 and the second red light emitting portion RED of the second area WB2 can face each other at a boundary between the first area WB1 and the second area WB2. A size of one color light emitting portion BE1 or GE1 or RE1 in the first area WB1 can be different than a size of the one color light emitting portion BE2 or GE2 or RE2 in the second area WB2 and the two different sized emitting portions for the same color can be disposed next to each other.

As shown in FIGS. 3 to 7, the first blue light emitting portion BE1, the second blue light emitting portion BE2, the first green light emitting portion GE1, the second green light emitting portion GE2, the first red light emitting portion RE1, the second red light emitting portion RE2, and the white light emitting portion WE are connected to their own independent or individual TFTs to be driven independently from the light emitting portions adjacent thereto.

In the light emitting display device according to the present disclosure, white can be expressed in three modes, such as first white light emission through only the white light emitting portion WE in the second area WB2 (e.g., first white mode), second white light emission through the light emitting portions BE2, GE2, RE2 and WE in the second area WB2 (e.g., second white mode), and third white light emission through all of the light emitting portions BE1, BE2, GE1, GE2, RE1, RE2 and WE in the first and second areas WB1 and WB2 (e.g., third white mode). The first, second and third white light emission modes can be selectively performed through selective signal application to the thin film transistors connected to each light emitting portion.

In the light emitting display device according to an embodiment of the present disclosure, therefore, white expression having different levels of intensity and color gamut is possible through selective driving of some or entire driving of all light emitting portions. In particular, white light emission is possible through the white light emitting portion WE in which a plurality of color light emitting layers emitting different colors of light overlap with each other, whereby white expression is possible by driving only the white light emitting portion WE, which has a limited area, among the light emitting portions provided on the substrate. In addition, when white light emission obtained through light summation of the second blue light emitting portion BE2, the second green light emitting portion GE2 and the second red light emitting portion RE2 of the second area WB2, in which pure color light emitting layers overlap with each other, and/or white light emission obtained through light summation of the first blue light emitting portion BE1, the first green light emitting portion GE1 and the first red light emitting portion RE1 of the first area WB1 is performed, unlike an area having mixed light emitting layers, as in the white light emitting portion WE, white expression can be variously changed, and in this way, color gamut can be extended.

In the light emitting display device according to the embodiment of the present disclosure, the combination of the blue light emitting portion, the green light emitting portion, and the red light emitting portion provided in each of the first area WB1 and the second area WB2 is not limited to the above-described combination. For example, each of the first area WB1 and the second area WB2 can be implemented through a combination of cyan, magenta, and yellow in order to emit white light. In the light emitting display device according to an embodiment of the present disclosure, however, the same color light emitting portions are provided in the first area WB1 and the second area WB2. Consequently, the first area WB1 and the second area WB2 can include the same color light emitting portions except the white light emitting portion may only be in the second area WB2 and absent from the first area WB1, but embodiments are not limited thereto.

In the light emitting display device shown in FIG. 2, the second red light emitting portion RE2 is trapezoidal (e.g., a long, thin trapezoid shape), and each of the other light emitting portions BE1, BE2, GE1, GE2, RE1 and WE has a triangular shape. However, the present disclosure is not limited thereto. In a light emitting display device according to another embodiment of the present disclosure, the shape of each light emitting portion can be changed such that an area at which deposition is commonly performed with respect to adjacent light emitting portions is easily disposed. For example, one of the light emitting portions BE1, BE2, GE1, GE2, RE1, RE2 and WE can have a shape of any one of a polygon, such as a quadrangle or a triangle, an oval, and a circle, or can have a polygonal basic structure having rounded corners.

In the light emitting display device according to the embodiment of the present disclosure, a plurality of blocks, each of which includes first and second areas WB1 and WB2, are repeatedly disposed on the substrate. Each block including first and second areas WB1 and WB2 can be defined as one pixel (e.g., one unit pixel including a plurality of subpixels).

As shown in FIG. 2, each of the white light emitting portion WE and the first and second red light emitting portions RE1 and RE2 can be disposed to have a long side in an X-axis direction. The first and second green light emitting portions GE1 and GE2 and the first and second blue light emitting portions BE1 and BE2 can be disposed in a Y-axis direction.

In the second area WB2 of FIG. 2, the white light emitting portion WE is provided among the second blue light emitting portion BE2, the second green light emitting portion GE2, and the second red light emitting portion RE2. Consequently, the path of the second blue light emitting portion BE2, the second green light emitting portion GE2, and/or the second red light emitting portion RE2 is increased, whereby it is possible to alleviate or prevent red or green leakage occurring at the time of low-gradation driving of the blue light emitting portion due to lateral current leakage. In other words, the second green light emitting portion GE2 and the second red light emitting portion RE2 are spaced farther apart from the second blue light emitting portion BE2 due to the white light emitting portion WE being disposed therebetween, and thus, the white light emitting portion WE can help better prevent leakage current from the second blue light emitting portion BE2 from unintentionally turning on the second green light emitting portion GE2 and/or the second red light emitting portion RE2.

The first area WB1 and the second area WB2 can face each other. That is, the first blue light emitting portion BE1 of the first area WB1 can face the second blue light emitting portion BE2 of the second area WB2, and the first green light emitting portion GE1 of the first area WB1 can face the second green light emitting portion GE2 of the second area WB2. In addition, the first red light emitting portion RE1 of the first area WB1 can face the white light emitting portion WE of the second area WB2, and the white light emitting portion WE and the second red light emitting portion RE2 can be disposed side by side in the second area WB2. For example, the white light emitting portion WE can be disposed between the first red light emitting portion RE1 of the first area WB1 and the second red light emitting portion RE2 of the second area WB2.

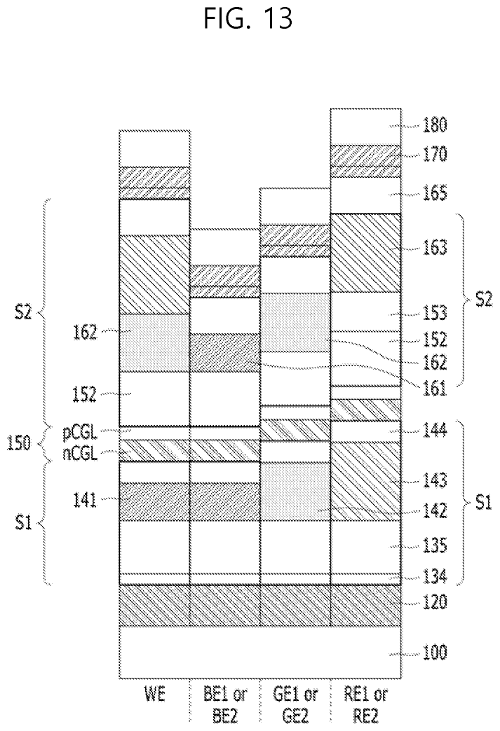

In FIG. 2, the white light emitting portion WE has the largest area, and each of the sum of the areas of the first and second blue light emitting portions BE1 and BE2, the sum of the areas of the first and second green light emitting portions GE1 and GE2, and the sum of the areas of the first and second red light emitting portions RE1 and RE2 is equal to or approximately equal to the size of the white light emitting portion WE. For example, when the areas of each color are added up, they form triangles that have the same size or at least approximately the same size (e.g., regarding areas, BE1+BE2=WE, and GE1+GE2=RE1+RE2, etc.). A method of manufacturing the light emitting display device having disposition of the light emitting portions of FIG. 2 will be described later with reference to FIGS. 13 to 16.

As shown in FIGS. 3 to 7, the thin film transistor array board 1000 can include a substrate 100, a thin film transistor TFT, and a first passivation film 108 and a second passivation film 109 configured to cover the thin film transistor TFT.

The thin film transistor TFT includes a semiconductor layer 103, a gate electrode 105 overlapping the semiconductor layer 103 in the state in which a gate dielectric film 104 is interposed therebetween, and a source electrode 106 and a drain electrode 107 connected to both sides of the semiconductor layer 103.

The semiconductor layer 103 can include at least one of an oxide semiconductor, amorphous silicon, and crystalline silicon. The semiconductor layer 103 can be formed by stacking a plurality of the same kind or different kinds of semiconductor materials. The semiconductor layer 103 can optionally further include a conductive layer provided at the part at which the source electrode 106 and the drain electrode 107 are connected to each other.

In the figures, a top gate type thin film transistor in which the gate electrode 105 is located above the semiconductor layer 103 is shown; however, embodiments of the present disclosure are not limited thereto. The thin film transistor included in the light emitting display device according to an embodiment of the present disclosure can be a bottom gate type thin film transistor in which the gate electrode is located under the semiconductor layer or a dual gate type thin film transistor in which gate electrodes are located above and under the semiconductor layer.

A light blocking layer 101 can be provided under the semiconductor layer 103 of the thin film transistor TFT to prevent generation of photocurrent in the semiconductor layer 103 due to light incident from below the substrate 100.

The light blocking layer 101 can be formed on the substrate 100 to extend in one direction in order to receive voltage from one side of the substrate 100. In this situation, it is possible to prevent electrical volatility of the light blocking layer 101 and to prevent an electrical effect or influence on the semiconductor layer 103.

The light blocking layer 101 can be formed in a single layer structure or a multilayer structure made of any one selected from the group including copper (Cu), molybdenum (Mo), aluminum (Al), chromium (Cr), gold (Au), titanium (Ti), nickel (Ni), neodymium (Nd), tantalum (Ta), and tungsten (W) or an alloy thereof.

The gate electrode 105, the source electrode 106, and the drain electrode 107 can be formed by selectively patterning the same material on the same layer. In addition, each of the gate electrode 105, the source electrode 106, and the drain electrode 107 can be formed in a single layer structure or a multilayer structure. For example, when each of the gate electrode 105, the source electrode 106, and the drain electrode 107 is formed in a single layer structure, any one selected from the group including molybdenum (Mo), aluminum (Al), chromium (Cr), gold (Au), titanium (Ti), nickel (Ni), neodymium (Nd), and copper (Cu) or an alloy thereof can be used. Also, when each of the gate electrode 105, the source electrode 106, and the drain electrode 107 is formed in a multilayer structure, a dual layer of molybdenum/aluminum-neodymium, molybdenum/aluminum, titanium/aluminum, or copper/molytitanium can be used. Alternatively, each of the gate electrode 105, the source electrode 106, and the drain electrode 107 can be formed in a triple-layer structure of 1 molybdenum/aluminum-neodymium/molybdenum, molybdenum/aluminum/molybdenum, titanium/aluminum/titanium, or molytitanium/copper/molytitanium. However, the present disclosure is not limited thereto, and each of the gate electrode 105, the source electrode 106, and the drain electrode 107 can be formed in a multilayer structure made of any one selected from the group including molybdenum (Mo), aluminum (Al), chromium (Cr), gold (Au), titanium (Ti), nickel (Ni), neodymium (Nd), and copper (Cu) or an alloy thereof.

A buffer layer 102 can be provided between the light blocking layer 101 and the semiconductor layer 103. The buffer layer 102 can prevent impurities from the substrate 100 from permeating the thin film transistor TFT or an area thereabove. The buffer layer 102 can be made of an inorganic dielectric film, such as an oxide film, a nitride film, or an oxy-nitride film. The buffer layer 102 can be constituted by a single film or a plurality of films.

The first passivation film 108 and the second passivation film 109 can be provided to protect the thin film transistor TFT. As an example, the first passivation film 108 can be an inorganic dielectric film, and the second passivation film 109 can be an organic dielectric film. The first passivation film 108 can be an oxide film, a nitride film, or an oxy-nitride film. The second passivation film 109 can be made of at least one of organic materials, such as photo acrylic, polyimide, benzocyclobutene, and acrylate.

The construction from the substrate 100 to the second passivation film 109 is referred to as a thin film transistor array board 1000 or a TFT layer.

The drain electrode 107 of the thin film transistor TFT is exposed through contact holes provided in the first and second passivation films 108 and 109, and is connected to a first electrode 120 provided in each of the light emitting portions BE1, BE2, GE1, GE2, RE1, RE2 and WE through the contact holes. The thin film transistor TFT of each of the light emitting portions BE1, BE2, GE1, GE2, RE1, RE2 and WE is independently provided, and therefore, each of the light emitting portions BE1, BE2, GE1, GE2, RE1, RE2, and WE can be independently driven via the corresponding thin film transistor TFT.

As shown in FIGS. 3 to 7, each of the first blue light emitting portion BE1, the second blue light emitting portion BE2, the first green light emitting portion GE1, the second green light emitting portion GE2, the first red light emitting portion RE1, the second red light emitting portion RE2, and the white light emitting portion WE includes a first electrode 120 and a second electrode 170 opposite each other, a plurality of stacks S1 and S2 sequentially provided between the first electrode 120 and the second electrode 170, and a charge generation layer 150 between the plurality of stacks. The first stack S1 and the second stack S2 include common layers 135, 144, 152, and 165 and light emitting layers 141, 142, 143, 161, 162, and 163.

Each of the light emitting portions BE1, BE2, GE1, GE2, RE1, RE2, and WE can be defined by an exposed part of a bank 130. I.e., the light emitting portions BE1, BE2, GE1, GE2, RE1, RE2, and WE may be provided between the banks 130. As the first electrodes 120 are only provided between the banks 130, light emission is only possible where the first and second electrodes 120, 170 overlap.

Specifically, referring to FIGS. 2 to 7, each of the first and second blue light emitting portions BE1 and BE2 adjacent to each other includes a first blue light emitting layer 141 in the first stack S1 and a second blue light emitting layer 161 in the second stack S2. In addition, each of the first and second green light emitting portions GE1 and GE2 adjacent to each other includes a first green light emitting layer 142 in the first stack S1 and a second green light emitting layer 162 in the second stack S2. Each of the first and second red light emitting portions RE1 and RE2 adjacent to each other includes a first red light emitting layer 143 in the first stack S1 and a second red light emitting layer 163 in the second stack S2. In other words, two stacks (S1, S2) are spread across many different light emitting portions (e.g., such as 7 different individual light emitting portions), each stack includes three different light emitting layers (R, G, B), and each of the light emitting portions includes at least some parts of both stacks so that each light emitting portion includes at least two light emitting layers, except for the white light emitting portion WE which includes three light emitting layers (e.g., R, G and B, in order to combine to output white light). For example, the first blue light emitting portion BE1 can include part of the first blue light emitting layer 141 from the first stack S1 and part of the second blue light emitting layer 161 from the second stack S2, the first red light emitting portion RE1 can include part of the first red light emitting layer 143 from the first stack S1 and part of the second red light emitting layer 163 from the second stack S2, while the white light emitting portion WE can include part of the first blue light emitting layer 141 from the first stack S1, part of the second green light emitting layer 162 of the second stack S2 and part of the second red light emitting layer 163 from the second stack S2. Further, some of the light emitting layers in each of the two stacks can extend across two or more light emitting portions in the pixel unit. In this way, the embodied invention can make more light emitting portions that have smaller sizes and pack them closer together while also using fewer masks, and the masks can have larger openings, which reduces manufacturing costs, shortens manufacturing times and improves yields.

Specifically, in a vertical structure of each of the first blue light emitting portion BE1 and the second blue light emitting portion BE2, a first hole transport layer 135, a first blue light emitting layer 141, a first electron transport layer 144, a charge generation layer 150, a second hole transport layer 152, a second blue light emitting layer 161, a second electron transport layer 165, and a second electrode 170 are sequentially provided on the first electrode 120.

The first and second blue light emitting portions BE1 and BE2 respectively include a first blue light emitting layer 141 and a second blue light emitting layer 161, and the first blue light emitting layer 141 and the second blue light emitting layer 161 overlap each other on the bank 130 between the first and second blue light emitting portions BE1 and BE2 (e.g., the same two blue light emitting layers in both of the two stacks extend across both of the first and second blue light emitting portions BE1 and BE2). Consequently, the first blue light emitting layer 141 can be formed in the first blue light emitting portion BE1, in the second blue light emitting portion BE2, and between the first and second blue light emitting portions BE1 and BE2 using a deposition mask having an aperture.

In a vertical structure of each of the first green light emitting portion GE1 and the second green light emitting portion GE2, a first hole transport layer 135, a first green light emitting layer 142, a first electron transport layer 144, a charge generation layer 150, a second hole transport layer 152, a second green light emitting layer 162, a second electron transport layer 165, and a second electrode 170 are sequentially provided on the first electrode 120.

The first and second green light emitting portions GE1 and GE2 respectively include a first green light emitting layer 142 and a second green light emitting layer 162 in an overlapping state. In addition, the first green light emitting layer 142 and the second green light emitting layer 162 overlap each other on the bank 130 between the first and second green light emitting portions GE1 and GE2 (e.g., the same two green light emitting layers in both of the two stacks extend across both of the first and second green light emitting portions GE1 and GE2). Consequently, the first green light emitting layer 142 can be formed in the first green light emitting portion GE1, in the second green light emitting portion GE2, and between the first and second green light emitting portions GE1 and GE2 using a deposition mask having an aperture.

In a vertical structure of each of the first red light emitting portion RE1 and the second red light emitting portion RE2, a first hole transport layer 135, a first red light emitting layer 143, a first electron transport layer 144, a charge generation layer 150, a second hole transport layer 152, a second red light emitting layer 163, a second electron transport layer 165, and a second electrode 170 are sequentially provided on the first electrode 120.

The first and second red light emitting portions RE1 and RE2 respectively include a first red light emitting layer 143 and a second red light emitting layer 163, and the first red light emitting layer 143 and the second red light emitting layer 163 overlap each other on the bank 130 between the first and second red light emitting portions RE1 and RE2 (e.g., the same two red light emitting layers in both of the two stacks extend across both of the first and second red light emitting portions RE1 and RE2). Consequently, the first red light emitting layer 143 can be formed in the first red light emitting portion RE1, in the second red light emitting portion RE2, and between the first and second red light emitting portions RE1 and RE2 using a deposition mask having an aperture.

The white light emitting portion WE includes a first hole transport layer 135, a first blue light emitting layer 141, a first electron transport layer 144, a charge generation layer 150, a second hole transport layer 152, a second green light emitting layer 162, a second red light emitting layer 163, a second electron transport layer 165, and a second electrode 170 sequentially provided on the first electrode 120.

The light emitting layer of the first stack S1 of the white light emitting portion WE is formed by extending the first blue light emitting layer 141 of the first and second blue light emitting portions BE1 and BE2 into the white light emitting portion WE.

In addition, the second stack S2 of the white light emitting portion WE is formed by extending the second green light emitting layer 162 of the first and second green light emitting portions GE1 and GE2 into the white light emitting portion WE and extending the second red light emitting layer 163 of the first and second red light emitting portions RE1 and RE2 into the white light emitting portion WE. In this way, the white light emitting portion WE includes red, green and blue light emitting layers which in combination can output white light.

The first and second red light emitting portions RE1 and RE2 respectively include the first red light emitting layer 143 and the second red light emitting layer 163, and the first red light emitting layer 143 and the second red light emitting layer 163 overlap each other on the bank 130 between the first and second red light emitting portions RE1 and RE2. Consequently, the first red light emitting layer 143 can be formed in the first red light emitting portion RE1, in the second red light emitting portion RE2, and between the first and second red light emitting portions RE1 and RE2 using a deposition mask having an aperture.

That is, the white light emitting portion WE shares the first blue light emitting layer 141 of the first stack S1 of the first and second blue light emitting portions BE1 and BE2 adjacent to each other, and shares the second green light emitting layer 162 of the second stack S2 of the first and second green light emitting portions GE1 and GE2 adjacent to each other and the second red light emitting layer 163 of the first and second red light emitting portions RE1 and RE2.

The portion of the first stack S1 over the white light emitting portion WE can be formed by extending the aperture when the first blue light emitting layer 141 of the first and second blue light emitting portions BE1 and BE2 adjacent to each other is formed, and the portion of the second stack S2 over the white light emitting portion WE can be formed by extending the aperture when the second green light emitting layer 162 of the first and second green light emitting portions GE1 and GE2 and the second red light emitting layer 163 of the first and second red light emitting portions RE1 and RE2 are formed, in this way, no separate deposition mask is needed for forming the white light emitting portion WE, and therefore it is possible to reduce the number of deposition masks required to provide the same number of light emitting portions. In other words, more light emitting portions can be formed while uses a fewer number of deposition masks.

In order to form each light emitting layer, the deposition mask is made of metal to have a fine aperture. Also, there are limits and costs associated with how small the aperture can be in the fine metal mask (e.g., a smaller aperture may increase the cost of the mask and increase the risk of manufacturing errors). The deposition mask is located under the substrate. The edge of the deposition mask is fixed, and a deposited material evaporated thereunder is transmitted through the aperture of the deposition mask. A central area distant from the fixed edge of the deposition mask droops, whereby a deposition area is misaligned, or the deposition area is invaded. As a result, it is difficult to implement ultrahigh resolution using only the aperture of the deposition mask. For the deposition mask, a number of deposition materials required during the process are independently supplied, and the deposition materials supplied to correspond to the area other than the aperture are discarded. As the number of deposition masks is increased, the amount of deposition materials used is increased, whereby production cost and additional process expenses are increased.

In the light emitting display device according to embodiments of the present disclosure, for example, the first blue light emitting layer 141 is shared by the first and second blue light emitting portions BE1 and BE2 and the white light emitting portion WE, the second green light emitting layer 162 is shared by the first and second green light emitting portions GE1 and GE2 and the white light emitting portion WE, and the second red light emitting layer 163 is shared by the first and second red light emitting portions RE1 and RE2, thus, it is possible to reduce the number of deposition masks to ⅓ of the number of light emitting portions provided to form the light emitting layers, which results in great savings, and reduces the risk of manufacturing errors since fewer steps are involved, there are fewer chances for errors to occur.

In addition, the second blue light emitting layer 161 is shared by the first and second blue light emitting portions BE1 and BE2, the first green light emitting layer 142 is shared by the first and second green light emitting portions GE1 and GE2, and the first red light emitting layer 143 is shared by the first and second red light emitting portions RE1 and RE2, whereby it is possible to reduce the number of deposition masks to ½ of the number of light emitting portions provided to form the light emitting layers.

Meanwhile, in FIGS. 3 to 7, an example in which the blue light emitting layer of the white light emitting portion WE is provided in the first stack S1; however, the present disclosure is not limited thereto. In the second stack S2, the second blue light emitting layer 161 can extend from the first and second blue light emitting portions BE1 and BE2 into the white light emitting portion WE adjacent thereto, and in the first stack S1, the first green light emitting layer 142 extending from the first and second green light emitting portions GE1 and GE2 adjacent to each other and the first red light emitting layer 143 extending from the first and second red light emitting portions RE1 and RE2 can be formed, which will be described below.

In the light emitting display device according to an embodiment of the present disclosure, as described above, each of the blue, green, and red light emitting portions is divided into two parts in the first area WB1 and the second area WB2 disposed in one block, and such division into two parts is possible by provision of the bank 130 between the light emitting portions without reducing the aperture of the deposition mask to the area corresponding to each light emitting portion, thus, a separate step for dividing the light emitting portions can be eliminated. In the light emitting display device according to an embodiment the present disclosure, therefore, fine partition of the subpixel is possible during a photolithography process without change of the deposition mask, whereby it is possible to easily implement high resolution.

Meanwhile, the layers provided between the first electrode 120 and the second electrode 170 except for the light emitting layers 141 to 143 and 161 to 163 can be common layers formed contiguous with the plurality of light emitting portions on the substrate 100 irrespective of the light emitting portions. The common layers can be formed using an open mask open to at least the active area.

For example, the common layers can include a first hole transport layer 135, a first electron transport layer 144, a charge generation layer 150, a second hole transport layer 152, and a second electron transport layer 165. In addition, each of the common layers can be formed in a single layer structure or a multilayer structure.

The first and second hole transport layers 135 and 152 are layers related to hole injection and/or hole transport. Depending on circumstances, the first hole transport layer 135 can further include a hole injection layer adjacent to the first electrode 120. Each of the first and second hole transport layers 135 and 152 can further include an electron blocking layer adjacent to the light emitting layer.

Each of the first and second electron transport layers 144 and 165 transports electrons to the light emitting layer adjacent thereto. Each of the first and second electron transport layers 144 and 165 can further include a hole blocking layer adjacent to the light emitting layer.

The second electron transport layer 165 can further include an electron injection layer adjacent to the second electrode 170.

The charge generation layer 150 can include an n-type charge generation layer nCGL configured to generate electrons and to supply the electrons to the electron transport layer 144 of the stack adjacent thereto and a p-type charge generation layer pCGL configured to generate holes and to supply the holes to the hole transport layer 152 of the stack adjacent thereto. The n-type charge generation layer nCGL can also perform the function of the electron transport layer of the lower stack. The p-type charge generation layer pCGL can also perform the function of the hole transport layer of the upper stack.

In the light emitting display device according to an embodiment of the present disclosure, the light emitting layers of the first and second blue light emitting portions BE1 and BE2, the first and second green light emitting portions GE1 and GE2, and the first and second red light emitting portions RE1 and RE2 are included in the stacks S1 and S2 divided by the charge generation layer 150, whereby it is possible to improve light emission efficiency of pure colors.

Also, in the light emitting display device according to an embodiment of the present disclosure, the first blue light emitting layer of one stack of the first and second blue light emitting portions BE1 and BE2 can be shared by the white light emitting portion, and in the stack different from the shared stack of the first and second blue light emitting portions BE1 and BE2, the green light emitting layer of the first and second green light emitting portions GE1 and GE2 and the red light emitting layer of the first and second red light emitting portions RE1 and RE2 can be shared by the white light emitting portion, whereby the white light emitting portion WE can be formed to have stacks equal in number to the first and second blue light emitting portions BE1 and BE2 adjacent thereto. However, the second green light emitting layer 162 and the second red light emitting layer 163 can be in contact with each other in one stack of the white light emitting portion WE, e.g., the second stack S2 in FIGS. 3 to 7. That is, the white light emitting portion WE can include different light emitting layers in the first and second stacks S1 and S2 (e.g., red and green from S2 and blue from S1), and the light emitting layers can be in contact with each other in one stack (e.g., red and green can touch each other in S2 in the white light emitting portion WE).

In the light emitting display device according to an embodiment of the present disclosure, as an example, the first electrode 120 can include a reflective electrode, and the second electrode 170 can be a transparent electrode or a transflective electrode. In this situation, light emitted from the light emitting element constituted by the first and second stacks S1 and S2 between the first and second electrodes 120 and 170 can exit to the outside through the second electrode 170.

For example, when the first electrode 120 includes a reflective electrode, the first electrode 120 can be formed in a multilayer structure including a transparent conductive film and an opaque conductive film that exhibits high reflection efficiency. The transparent conductive film of the first electrode 120 can be made of a material that has a relatively large work function, such as indium tin oxide (ITO) or indium zinc oxide (IZO), and the opaque conductive film can be formed in a single layer structure or a multilayer structure made of any one selected from the group including silver (Ag), aluminum (Al), copper (Cu), molybdenum (Mo), titanium (Ti), nickel (Ni), chromium (Cr), and tungsten (W) or an alloy thereof. For example, the first electrode 120 can be formed in a structure in which a transparent conductive film, an opaque conductive film, and a transparent conductive film are sequentially stacked or a structure in which a transparent conductive film and an opaque conductive film are sequentially stacked.

The second electrode 170 can be made of a transparent conductive material, such as indium tin oxide (ITO) or indium zinc oxide (IZO), or can be made of silver (Ag), aluminum (Al), magnesium (Mg), calcium (Ca), ytterbium (Yb), or an alloy including at least one thereof, which has a small thickness sufficient to transmit light.

In the light emitting display device according to an embodiment of the present disclosure, as another example, the first electrode 120 can be a transparent electrode, and the second electrode 170 can be a reflective electrode. In this situation, light emitted from the light emitting element constituted by the first and second stacks S1 and S2 between the first and second electrodes 120 and 170 can exit to the outside through the first electrode 120. In this situation, the thin film transistor TFT can be disposed so as not to overlap with the light emitting portion of the first electrode 120 and to overlap with the bank 130 in order to improve transmittance of light emitted from the first electrode 120.

Light emitted from the first blue light emitting layer 141 and the second blue light emitting layer 161 has an emission peak at a wavelength of 410 nm to 490 nm.

Light emitted from the first green light emitting layer 142 and the second green light emitting layer 162 has an emission peak at a wavelength of 510 nm to 590 nm.

Light emitted from the first red light emitting layer 143 and the second red light emitting layer 163 has an emission peak at a wavelength of 600 nm to 650 nm.

Although each light emitting portion has two stacks in the above example, the present disclosure is not limited thereto. For example, each light emitting portion can be implemented to have three or more stacks between the first and second electrodes.

For example, when each light emitting portion has three or more stacks, the red light emitting layer and the green light emitting layer can extend from the red light emitting portion and the green light emitting portion into the white light emitting portion to be included in one or more stacks, and the blue light emitting layer can be extended to be included in two or more stacks.

In the light emitting display device according to an embodiment of the present disclosure, color light emitting layers that emits the same color of light overlap with each other in the first and second blue light emitting portions, the first and second green light emitting portions, and the first and second red light emitting portions, whereby it is possible to improve color purity. In addition, the white light emitting portion is located in an area surrounded by the first blue light emitting portion, the first green light emitting portion, and the first red light emitting portion (e.g., due to the nearby adjacent light emitting portions of each color). In this situation, the white light emitting portion is provided to be separated from each color light emitting portion. In the light emitting display device, therefore, white color expression can be extended, and white efficiency can be improved.

The light emitting layer of the white light emitting portion is formed in the same process as the process of forming the light emitting layer in one stack of the first and second blue light emitting portions, the first and second green light emitting portions, and the first and second red light emitting portions. Consequently, it is possible to provide the white light emitting portion without an additional deposition mask, and therefore it is possible to simplify the process.

In the light emitting display device according to an embodiment of the present disclosure, the color light emitting layer is shared by the color light emitting portions and the white light emitting portion, whereby it is possible to implement high resolution without reducing the area of the aperture of the mask used to form the color light emitting layer (e.g., a mask with a larger aperture can be used, even though the light emitting portions are small). It is possible to provide a white light emitting portion having a size equivalent to ½ or ⅓ of the area of the aperture of the deposition mask, whereby it is possible to implement high resolution without development or change of equipment.

Also, in the light emitting display device according to an embodiment of the present disclosure, the area of the material used to form the color light emitting layer extends into the white light emitting portion, not the single color light emitting portion, whereby it is possible to increase the effective deposition area of the material of the color light emitting layer and to increase material utilization rate, and therefore it is possible to achieve environmental improvement and reduce waste.

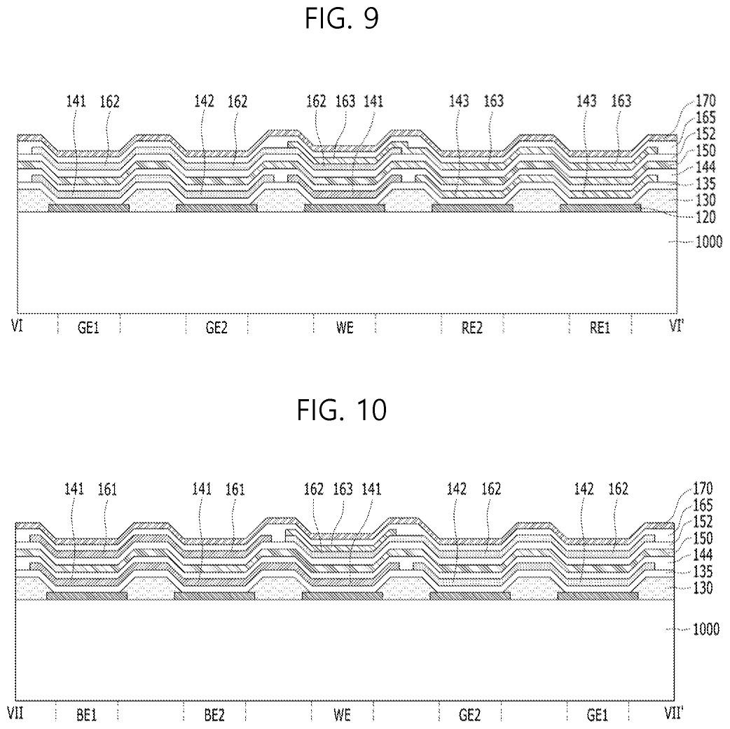

FIG. 8 is a plan view showing a light emitting display device according to a second embodiment of the present disclosure. FIG. 9 is a sectional view taken along line VI-VI′ of FIG. 8, and FIG. 10 is a sectional view taken along line VII-VII′ of FIG. 8.

Referring to FIG. 8, a second blue light emitting portion BE2, a second green light emitting portion GE2, and a second red light emitting portion RE2, which surround a white light emitting portion WE, are disposed to extend along sides of the white light emitting portion WE in longitudinal directions thereof (e.g., similar to a three leaf clover type of arrangement, or a shape of three overlapping triangles that can have a symmetrical type of arrangement about a center point).

Consequently, the second red light emitting portion RE2 is disposed in a horizontal axis direction, and a first red light emitting portion RE1 is disposed in the horizontal axis direction to be parallel to the second red light emitting portion RE2.

The second blue light emitting portion BE2 is disposed in a direction inclined by about 60° relative to the horizontal axis direction, and a first blue light emitting portion BE1 is disposed parallel to the second blue light emitting portion BE2.

The second green light emitting portion GE2 is disposed in a direction inclined by about 120° relative to the horizontal axis direction, and a first green light emitting portion GE1 is disposed in parallel to the second green light emitting portion GE2.

The light emitting display device according to the second embodiment of the present disclosure includes a block B1 including a first area WB1 including a first blue light emitting portion BE1, a first green light emitting portion GE1, and a first red light emitting portion RE1 and a second area WB2 including a second blue light emitting portion BE2, a second green light emitting portion GE2, a second red light emitting portion RE2, and a white light emitting portion WE. As an example, blocks B1 can be repeatedly disposed in the horizontal axis direction.

For example, a first blue light emitting layer 141 can be formed through a blue mask aperture BM_A that opens the first blue light emitting portion BE1, the second blue light emitting portion BE2, and the white light emitting portion WE.

A second green light emitting layer 162 can be formed through a green mask aperture GM_A that opens the first green light emitting portion GE1, the second green light emitting portion GE2, and the white light emitting portion WE.

A second red light emitting layer 163 can be formed through a red mask aperture RM_A that opens the first red light emitting portion RE1, the second red light emitting portion RE2, and the white light emitting portion WE.

The blue mask aperture BM_A, the green mask aperture GM_A, and the red mask aperture RM_A share the white light emitting portion WE, whereby different light emitting layers can be provided in different stacks and overlap with each other in the white light emitting portion WE.

As shown in FIG. 8, neighboring blocks B1 can be repeatedly disposed in a horizontal direction or a vertical direction.

In an example shown in FIG. 8, the longitudinal direction of the first and second red light emitting portions RE1 and RE2, the longitudinal direction of the first and second green light emitting portions GE1 and GE2, and the longitudinal direction of the first and second blue light emitting portions BE1 and BE2 can be interchangeable.

The second area WB2 includes a white light emitting portion WE and a second blue light emitting portion BE2, a second green light emitting portion GE2, and a second red light emitting portion RE2, which surround the white light emitting portion WE. A first area WB1 including a first subarea WB1_B including a first blue light emitting portion BE1 adjacent to the second blue light emitting portion BE2, a second subarea WB1_G adjacent to the second green light emitting portion GE2, and a third subarea WB1_R adjacent to the second red light emitting portion RE2 is provided outside the second area WB2.

In the light emitting display device according to the second embodiment of the present disclosure, as shown in FIGS. 9 and 10, a first blue light emitting portion BE1, a second blue light emitting portion BE2, a first green light emitting portion GE1, a second green light emitting portion GE2, a first red light emitting portion RE1, a second red light emitting portion RE2, and a white light emitting portion WE are disposed on a thin film transistor array board 1000. Each of the first blue light emitting portion BE1, the second blue light emitting portion BE2, the first green light emitting portion GE1, the second green light emitting portion GE2, the first red light emitting portion RE1, the second red light emitting portion RE2, and the white light emitting portion WE includes a first electrode 120 and a second electrode 170 opposite each other, a plurality of stacks S1 and S2 sequentially provided between the first electrode 120 and the second electrode 170, and a charge generation layer 150 provided between the plurality of stacks, in which the first stack S1 and the second stack S2 include common layers 135, 144, 152, and 165 and light emitting layers 141, 142, 143, 161, 162, and 163.

Each of the light emitting portions BE1, BE2, GE1, GE2, RE1, RE2 and WE can be defined by an exposed part of a bank 130.

A first blue light emitting layer 141 of the second blue light emitting portion BE2 adjacent to the white light emitting portion WE is shared in the first stack S1 of the white light emitting portion WE, and a second green light emitting layer 162 of the second green light emitting portion GE2 and a second red light emitting layer 163 of the second red light emitting portion RE2 are shared in the second stack S2.

A description of the same construction of the second embodiment as the first embodiments will be omitted.

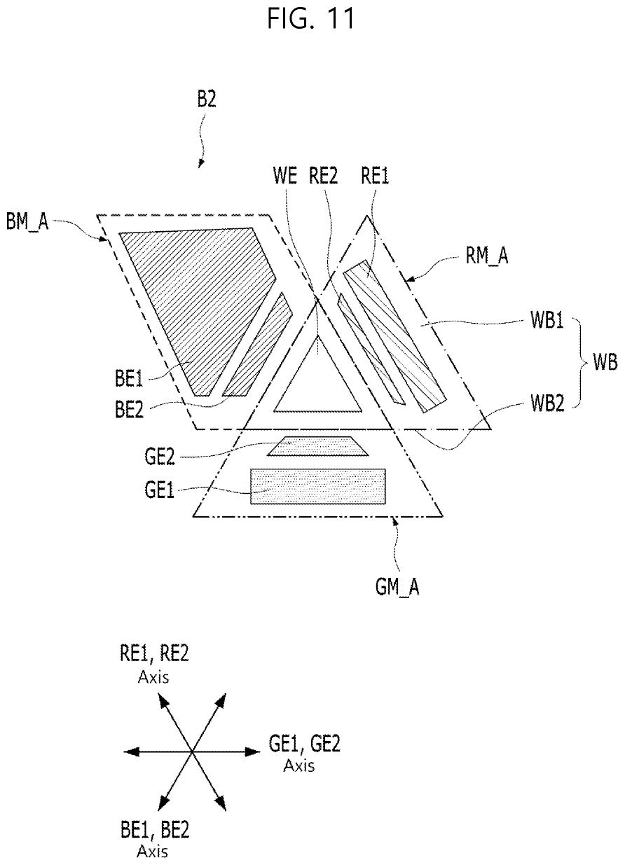

FIG. 11 is a plan view showing a light emitting display device according to a third embodiment of the present disclosure.

Referring to FIG. 11, the light emitting display device according to the third embodiment of the present disclosure includes a block B2 including a first area WB1 including a first blue light emitting portion BE1, a first green light emitting portion GE1, and a first red light emitting portion RE1 and a second area WB2 including a second blue light emitting portion BE2, a second green light emitting portion GE2, a second red light emitting portion RE2, and a white light emitting portion WE. As an example, the block B2 can have an approximate parallelogram shape, and blocks can be repeatedly disposed in a diagonal direction. For example, the area for the blue light emitting portions can be larger than areas of the red, green and white light emitting portions (e.g., providing a lopsided shape or asymmetrical shape).

In the second area WB2, the second blue light emitting portion BE2, the second green light emitting portion GE2, and the second red light emitting portion RE2, which surround the white light emitting portion WE, are disposed to extend along sides of the white light emitting portion WE in longitudinal directions thereof.

Consequently, the second green light emitting portion GE2 is disposed in a horizontal axis direction, and the first green light emitting portion GE1 is disposed in the horizontal axis direction to be parallel to the second green light emitting portion GE2.

The second red light emitting portion RE2 is disposed in a direction inclined by about 60° relative to the horizontal axis direction, and the first red light emitting portion RE1 is disposed parallel to the second red light emitting portion RE2.

The second blue light emitting portion BE2 is disposed in a direction inclined by about 120° relative to the horizontal axis direction, and the first blue light emitting portion BE1 is disposed parallel to the second blue light emitting portion BE2.

For example, a first blue light emitting layer of the first blue light emitting portion BE1 can be formed through a blue mask aperture BM_A that opens the first blue light emitting portion BE1, the second blue light emitting portion BE2, and the white light emitting portion WE.

A second green light emitting layer of the second green light emitting portion GE2 can be formed through a green mask aperture GM_A that opens the first green light emitting portion GE1, the second green light emitting portion GE2, and the white light emitting portion WE.

A second red light emitting layer of the second red light emitting portion RE2 can be formed through a red mask aperture RM_A that opens the first red light emitting portion RE1, the second red light emitting portion RE2, and the white light emitting portion WE.

The blue mask aperture BM_A, the green mask aperture GM_A, and the red mask aperture RM_A share the white light emitting portion WE, whereby different light emitting layers can be provided in different stacks of the white light emitting portion WE.

In the light emitting display device according to the third embodiment of the present disclosure, as shown in FIG. 11, the size of the first blue light emitting portion BE1 can be greater than the size of each of the other light emitting portions in order to improve blue efficiency to be higher than other color efficiencies in the first area WB1.

The second area WB2 includes a white light emitting portion WE and a second blue light emitting portion BE2, a second green light emitting portion GE2, and a second red light emitting portion RE2, which surround the white light emitting portion WE. A first area WB1 including a first subarea including a first blue light emitting portion BE1 adjacent to the second blue light emitting portion BE2, a second subarea WB1_G adjacent to the second green light emitting portion GE2, and a third subarea WB1_R adjacent to the second red light emitting portion RE2 is provided outside the second area WB2.

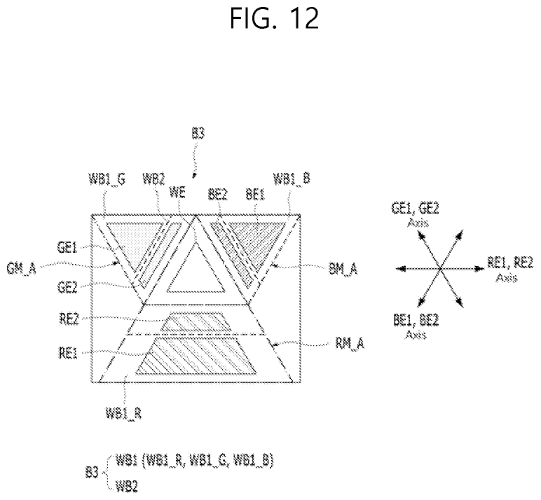

FIG. 12 is a plan view showing a light emitting display device according to a fourth embodiment of the present disclosure.

Referring to FIG. 12, the light emitting display device according to the fourth embodiment of the present disclosure includes a block B3 including a first area WB1 including a first blue light emitting portion BE1, a first green light emitting portion GE1, and a first red light emitting portion RE1 and a second area WB2 including a second blue light emitting portion BE2, a second green light emitting portion GE2, a second red light emitting portion RE2, and a white light emitting portion WE.

As an example, the block B3 has a shape including an upper trapezoid and a lower trapezoid (e.g., for example block B3 can have an hourglass shape), each of the middle of which is concave in a vertical direction and each of which has a short side on an imaginary center line. In a horizontal direction, blocks B3 can be repeatedly disposed such that the upper trapezoid and the lower trapezoid are engaged with each other at sides of neighboring blocks B3.

In the second area WB2, the second blue light emitting portion BE2, the second green light emitting portion GE2, and the second red light emitting portion RE2, which surround the white light emitting portion WE, are disposed to extend along sides of the white light emitting portion WE in longitudinal directions thereof.

Consequently, the second red light emitting portion RE2 is disposed in a horizontal axis direction, and the first red light emitting portion RE1 is disposed in the horizontal axis direction to be parallel to the second red light emitting portion RE2.

The second blue light emitting portion BE2 is disposed in a direction inclined by about 60° relative to the horizontal axis direction, and the first blue light emitting portion BE1 is disposed parallel to the second blue light emitting portion BE2.

The second green light emitting portion GE2 is disposed in a direction inclined by about 120° relative to the horizontal axis direction, and the first green light emitting portion GE1 is disposed parallel to the second green light emitting portion GE2.

In the light emitting display device according to the fourth embodiment of the present disclosure, the size of the first red light emitting portion RE1 can be greater than the size of each of the other light emitting portions in order to improve red efficiency to be higher than other color efficiencies in the first area WB1.

The second area WB2 includes a white light emitting portion WE and a second blue light emitting portion BE2, a second green light emitting portion GE2, and a second red light emitting portion RE2, which surround the white light emitting portion WE. A first area WB1 including a first subarea WB1_B including a first blue light emitting portion BE1 adjacent to the second blue light emitting portion BE2, a second subarea WB1_G adjacent to the second green light emitting portion GE2, and a third subarea WB1_R adjacent to the second red light emitting portion RE2 is provided outside the second area WB2.

For example, a first blue light emitting layer can be formed through a blue mask aperture BM_A that opens the first blue light emitting portion BE1, the second blue light emitting portion BE2, and the white light emitting portion WE.

A second green light emitting layer can be formed through a green mask aperture GM_A that opens the first green light emitting portion GE1, the second green light emitting portion GE2, and the white light emitting portion WE.

A second red light emitting layer can be formed through a red mask aperture RM_A that opens the first red light emitting portion RE1, the second red light emitting portion RE2, and the white light emitting portion WE.

The blue mask aperture BM_A, the green mask aperture GM_A, and the red mask aperture RM_A share the white light emitting portion WE, whereby different light emitting layers can be provided in different stacks of the white light emitting portion WE.

Hereinafter, a method of manufacturing the light emitting display device according to the present disclosure will be described.

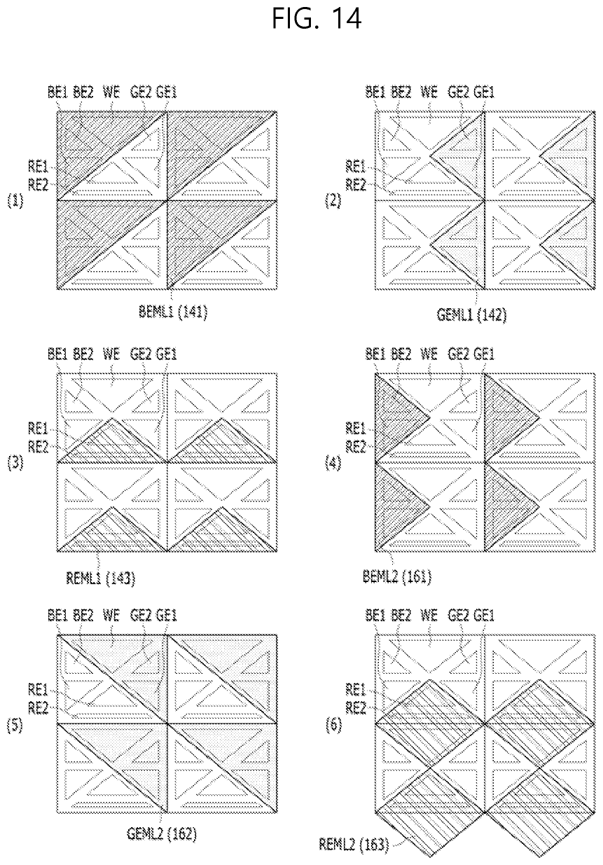

FIG. 13 is a sectional view showing a light emitting display device according to a fifth embodiment of the present disclosure, and FIG. 14 is a plan view showing a method of manufacturing the light emitting display device of FIG. 13.

Referring to FIG. 13, the light emitting display device according to the fifth embodiment of the present disclosure is almost identical in construction to the light emitting display device described with reference to FIGS. 2 to 7 except that a hole injection layer 134 is further provided under a first hole transport layer 135 and a hole transport auxiliary layer 153 is further provided on a second hole transport layer 152 in first and second red light emitting portions RE1 and RE2. In addition, a capping layer 180 configured to protect a light emitting element of each light emitting portion and to improve optical extraction is further provided on a second electrode 170.

Such a capping layer 180 may be applied in all embodiments.

An example of the method of manufacturing the light emitting display device according to the present disclosure will be described with reference to FIG. 14.

As shown in FIG. 13, a first electrode 120, a hole injection layer 134, and a first hole transport layer 135 are formed at each of light emitting portions WE, BE1, BE2, GE1, GE2, RE1, and RE2 on a substrate 100.

Subsequently, as shown in FIG. 14 part (1), a first blue light emitting layer 141 is formed on the first hole transport layer 135 over the white light emitting portion WE and the first and second blue light emitting portions BE1 and BE2 using a first deposition mask.

Subsequently, as shown in FIG. 14 part (2), a first green light emitting layer 142 is formed on the first hole transport layer 135 over the first and second green light emitting portions GE1 and GE2 using a second deposition mask.

Subsequently, as shown in FIG. 14 part (3), a first red light emitting layer 143 is formed on the first hole transport layer 135 over the first and second red light emitting portions RE1 and RE2 using a third deposition mask.

Subsequently, as shown in FIG. 13, a first electron transport layer 144, a charge generation layer 150, and a second hole transport layer 152 are sequentially formed.

Subsequently, a hole transport auxiliary layer 153 is optionally formed on the second hole transport layer 152 over the first and second red light emitting portions RE1 and RE2 using a fourth deposition mask.

The hole transport auxiliary layer 153 is provided to adjust the optical distance for each color. The hole transport auxiliary layer 153 is further provided when the optical distance is not sufficiently secured due to the thickness of each light emitting layer. The hole transport auxiliary layer can also be further provided at the first and second green light emitting portions GE1 and GE2, as needed.

The hole transport auxiliary layer 153 can be omitted when the optical distance is sufficiently secured due to the thickness of each light emitting layer. In this situation, the fourth deposition mask can also be omitted.

Subsequently, as shown in FIG. 14 part (4), a second blue light emitting layer 161 is formed on the second hole transport layer 152 over the first and second blue light emitting portions BE1 and BE2 using a fifth deposition mask.

Subsequently, as shown in FIG. 14 part (5), a second green light emitting layer 162 is formed on the second hole transport layer 152 over the first and second green light emitting portions GE1 and GE2 and the white light emitting portion WE using a sixth deposition mask.

Subsequently, as shown in FIG. 14 part (6), a second red light emitting layer 163 is formed on the second hole transport layer 152 over the first and second red light emitting portions RE1 and RE2 and on the second hole transport layer 152 of the white light emitting portion WE using a seventh deposition mask.

Subsequently, a second electron transport layer 165, a second electrode 170, and a capping layer 180 are sequentially formed. The second electron transport layer 165, the second electrode 170, and the capping layer 180 can be formed using an open mask.

Meanwhile, in the method of manufacturing the light emitting display device, parts (1) to (6) of FIG. 14 refer to the sequence of the deposition masks used when the layers provided between the first electrode 120 and the second electrode 170 are formed.

In the first stack, the sequence of the first blue light emitting layer 141, the first green light emitting layer 142, and the first red light emitting layer 143 can be changed.

In the second stack, the sequence of the second blue light emitting layer 161, the second green light emitting layer 162, and the second red light emitting layer 163 can be changed.

For example, in each stack, the green light emitting layer and/or the red light emitting layer can be formed earlier than the blue light emitting layer.

Since the green light emitting layer and the red light emitting layer abut each other or are in contact with each other in the light emitting display device according to the present disclosure, the green light emitting layer and the red light emitting layer can be formed in different sequences in the same stack.

A method of manufacturing a light emitting display device according to another embodiment of the present disclosure will be described.

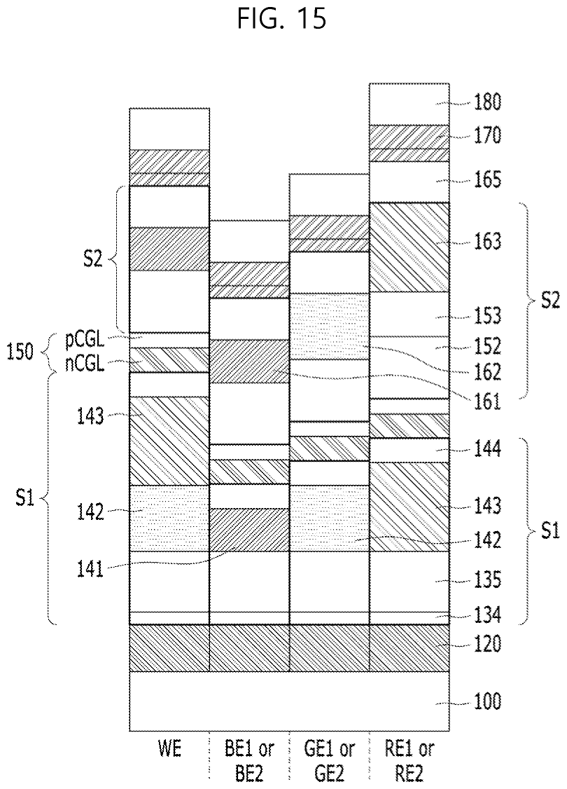

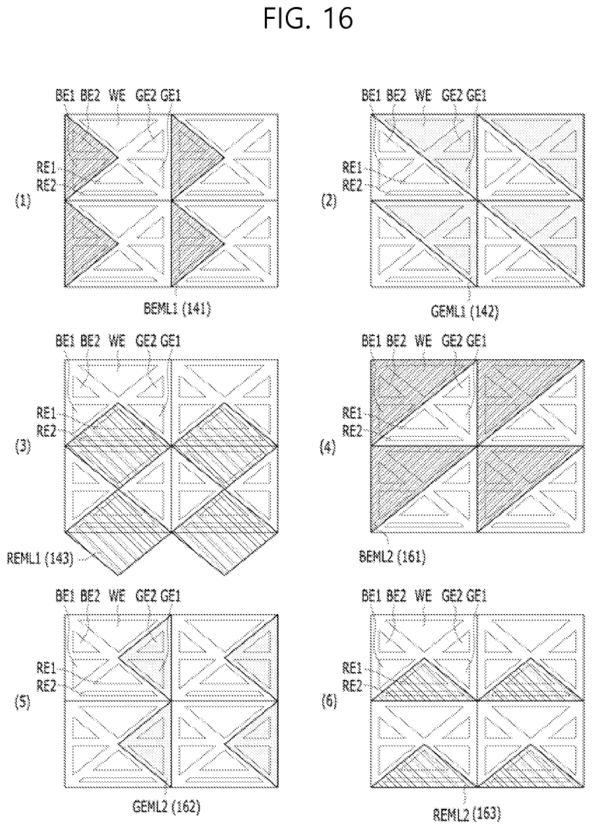

FIG. 15 is a sectional view showing a light emitting display device according to a sixth embodiment of the present disclosure, and FIG. 16 is a plan view showing a method of manufacturing the light emitting display device of FIG. 15.

Referring to FIG. 15, the light emitting display device according to the sixth embodiment of the present disclosure is identical in construction to the light emitting display device according to the fifth embodiment of the present disclosure except that, in a white light emitting portion WE, a red light emitting layer and a green light emitting layer are disposed in a first stack S1 and a blue light emitting layer is disposed in a second stack S2.

An example of the method of manufacturing the light emitting display device according to the present disclosure will be described with reference to FIGS. 15 and 16.

As shown in FIG. 15, a first electrode 120, a hole injection layer 134, and a first hole transport layer 135 are formed at each of light emitting portions WE, BE1, BE2, GE1, GE2, RE1, and RE2 on a substrate 100.

Subsequently, as shown in FIG. 16 part (1), a first blue light emitting layer 141 is formed on the first hole transport layer 135 over the first and second blue light emitting portions BE1 and BE2 using a first deposition mask.

Subsequently, as shown in FIG. 16 part (2), a first green light emitting layer 142 is formed on the first hole transport layer 135 over the white light emitting portion WE and the first and second green light emitting portions GE1 and GE2 using a second deposition mask.

Subsequently, as shown in FIG. 16 part (3), a first red light emitting layer 143 is formed on the first green light emitting layer 142 of the white light emitting portion WE and on the first hole transport layer 135 over the first and second red light emitting portions RE1 and RE2 using a third deposition mask.

Subsequently, as shown in FIG. 15, a first electron transport layer 144, a charge generation layer 150, and a second hole transport layer 152 are sequentially formed.

Subsequently, a hole transport auxiliary layer 153 is optionally formed on the second hole transport layer 152 over the first and second red light emitting portions RE1 and RE2 using a fourth deposition mask.

The hole transport auxiliary layer 153 is provided to adjust the optical distance for each color. The hole transport auxiliary layer 153 is further provided when the optical distance is not sufficiently secured due to the thickness of each light emitting layer. The hole transport auxiliary layer can also be further provided at the first and second green light emitting portions GE1 and GE2, as needed.

The hole transport auxiliary layer 153 can be omitted when the optical distance is sufficiently secured due to the thickness of each light emitting layer. In this situation, the fourth deposition mask can also be omitted.

Subsequently, as shown in FIG. 16 part (4), a second blue light emitting layer 161 is formed on the second hole transport layer 152 over the white light emitting portion WE and the first and second blue light emitting portions BE1 and BE2 using a fifth deposition mask.

Subsequently, as shown in FIG. 16 part (5), a second green light emitting layer 162 is formed on the second hole transport layer 152 over the first and second green light emitting portions GE1 and GE2 using a sixth deposition mask.

Subsequently, as shown in FIG. 16 part (6), a second red light emitting layer 163 is formed on the second hole transport layer 152 over the first and second red light emitting portions RE1 and RE2 using a seventh deposition mask.

Subsequently, a second electron transport layer 165, a second electrode 170, and a capping layer 180 are sequentially formed. The second electron transport layer 165, the second electrode 170, and the capping layer 180 can be formed using an open mask.

In the first stack, the sequence of the first blue light emitting layer 141, the first green light emitting layer 142, and the first red light emitting layer 143 can be changed.

In the second stack, the sequence of the second blue light emitting layer 161, the second green light emitting layer 162, and the second red light emitting layer 163 can be changed.

For example, in each stack, the green light emitting layer and/or the red light emitting layer can be formed earlier than the blue light emitting layer.

Hereinafter, efficiency of the light emitting display device according to the present disclosure will be described through experiments.

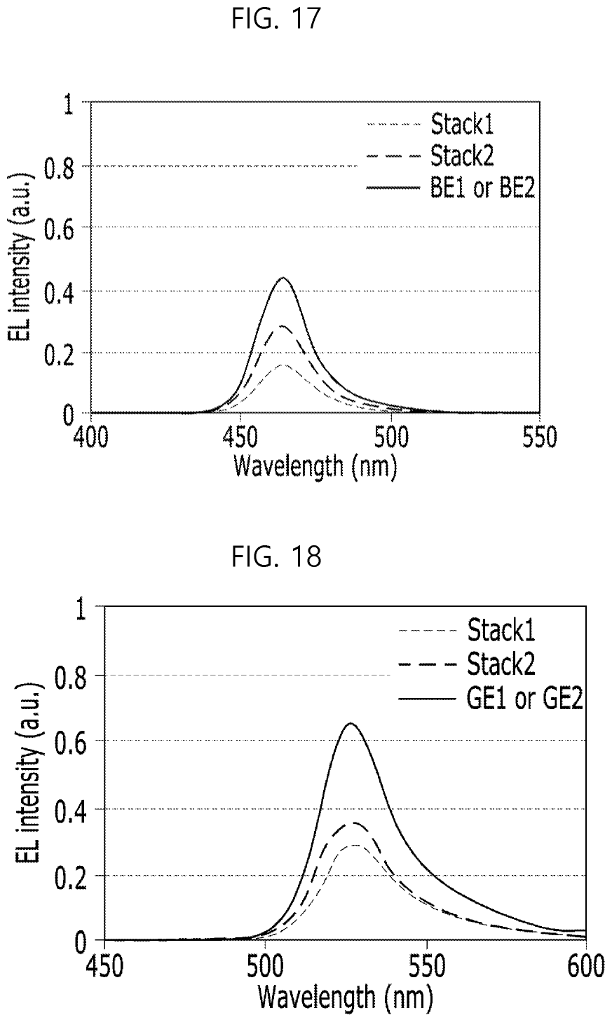

FIGS. 17 to 19 are graphs showing individual stack efficiency and overall stack efficiency of the blue light emitting portion, the green light emitting portion, and the red light emitting portion of the light emitting display device according to an embodiment of the present disclosure.

Referring to FIG. 17 and Table 1, it can be seen that, when each of the first and second blue light emitting portions BE1 and BE2 of the light emitting display device according to an embodiment of the present disclosure has a stack structure, it is possible to remarkably improve color efficiency even through drive voltage is not greatly increased, compared to individual efficiency of the first stack S1 and the second stack S2.

TABLE 1

| @5 mA/cm² | S1 | S2 | BE1, BE2 |
|---|---|---|---|
| Eff. (cd/A) | 5.6 | 8.8 | 14.3 |
| Voltage (V) | 7.43 | 6.63 | 7.97 |

TABLE 2

| @5 mA/cm² | S1 | S2 | GE1, GE2 |
|---|---|---|---|
| Eff. (cd/A) | 122.0 | 134.5 | 256.0 |
| Voltage (V) | 6.88 | 6.43 | 2.31 |

Also, referring to FIG. 18 and Table 2, it can be seen that, when each of the first and second green light emitting portions GE1 and GE2 of the light emitting display device according to an embodiment of the present disclosure has a stack structure, it is possible to remarkably improve color efficiency even though drive voltage is not greatly increased, compared to the individual efficiency of each of the first stack S1 and the second stack S2.

TABLE 3

| @5 mA/cm² | S1 | S2 | RE1, RE2 |
|---|---|---|---|
| Eff. (cd/A) | 34.8 | 36.2 | 70.0 |
| Voltage (V) | 6.23 | 6.05 | 6.50 |

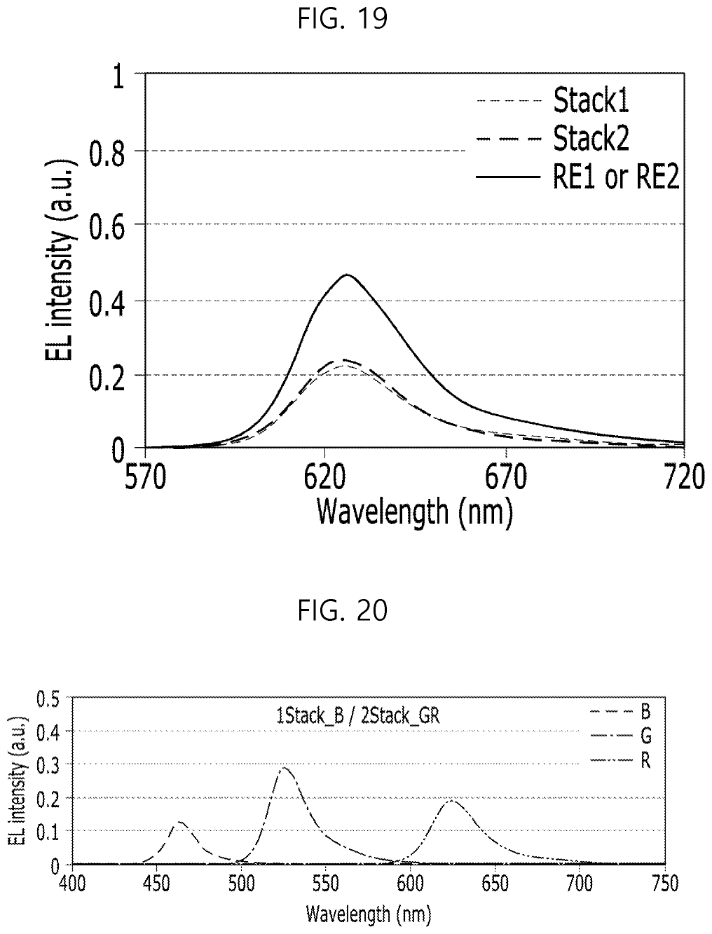

Similarly, referring to FIG. 19 and Table 3, it can be seen that, when each of the first and second red light emitting portions RE1 and RE2 of the light emitting display device according to an embodiment of the present disclosure has a stack structure, it is possible to remarkably improve color efficiency even though drive voltage is not greatly increased, compared to individual efficiency of the first stack S1 and the second stack S2.

FIG. 20 is a graph showing a light emission spectrum of the white light emitting portion of the light emitting display device according to an embodiment of the present disclosure.

FIG. 20 and Table 4 show efficiency and illuminance of the light emitting element configured such that the first blue light emitting layer is provided in the first stack of the white light emitting portion and the green light emitting layer and the red light emitting layer are provided to be in contact with each other in the second stack, as shown in FIGS. 2 to 7. It can be seen that efficiency of the white light emitting portion is 176.3 Cd/A, and illuminance of the white light emitting portion is 600 nits. This means that the white light emitting portion is capable of sufficiently expressing white and is rather bright.

TABLE 4

| @600 nit | Blue (S1) | Green (S2) | Red(S2) | White (B/GR) |
|---|---|---|---|---|
| Eff. (cd/A) | 5.6 | 134.5 | 36.2 | 176.3 |
| L(nit) | 19.1 | 457.9 | 123.2 | 600 |

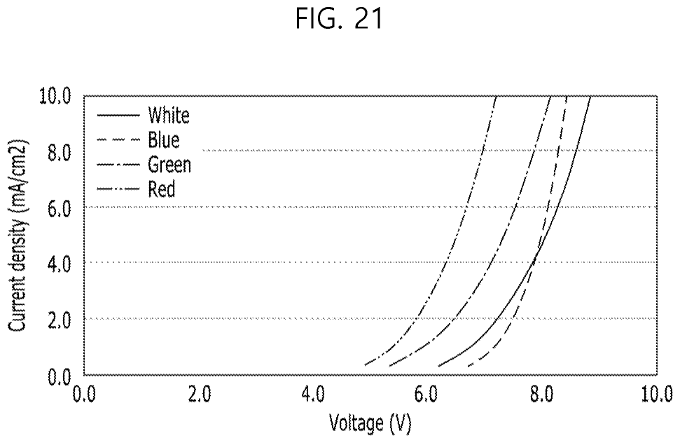

FIG. 21 is a graph showing I-V characteristics of blue, green, red, and white of the light emitting display device according to an embodiment of the present disclosure.

Referring to FIG. 21, it can be seen that, when the light emitting display device according to the present disclosure is applied, white driving is possible to a level similar to the blue light emitting portion, which has the highest drive voltage.

That is, in the light emitting display device according to an embodiment of the present disclosure, the white light emitting portion can be driven even though drive voltage is applied up to the level of the blue light emitting portion, which means that low-power driving is possible while power consumption is maintained when white light is emitted. In addition, referring to FIG. 2, when the blue light emitting portion, the green light emitting portion, and the red light emitting portion are provided in the first area WB1 and/or the second area WB2, white expression having extended color gamut is possible. In this situation, drive voltage of each light emitting portion can be reduced to the level of the blue light emitting portion or less, whereby it is possible to maintain low power without a great increase in power consumption of the light emitting portion in specific areas.

Also, in the light emitting display device according to an embodiment of the present disclosure, the white light emitting portion WE is provided among the second blue light emitting portion BE2, the second green light emitting portion GE2, and the second red light emitting portion RE2 in the second area WB2 of FIG. 2 (e.g., the white light emitting portion WE can space the other light emitting portions father apart from each other). Consequently, the path of the second blue light emitting portion BE2, the second green light emitting portion GE2, and/or the second red light emitting portion RE2 is increased, whereby it is possible to alleviate or prevent red or green leakage occurring at the time of low-gradation driving of the blue light emitting portion due to lateral current leakage.

In the light emitting display device according to an embodiment of the present disclosure, the bank area is increased in the high-resolution structure, whereby it is possible to increase resistance to lateral current leakage as the result of increase in area of the bank between adjacent subpixels, and therefore it is possible to prevent low-gradation color leakage due to lateral current leakage.

A light emitting display device according to an embodiment of the present disclosure can comprise a first area on a substrate, the first area comprising a first light emitting portion to emit a first color of light, a second light emitting portion to emit a second color of light, and a third light emitting portion to emit a third color of light, and a second area adjacent to the first area on the substrate, the second area comprising a fourth light emitting portion to emit the first color of light, a fifth light emitting portion to emit the second color of light, a sixth light emitting portion to emit the third color of light, and a seventh light emitting portion to emit white light. Each of the first to seventh light emitting portions can include a plurality of stacks, and a light emitting layer provided in at least one of the stacks among the fourth to sixth light emitting portions is continuous with the seventh light emitting portion.

In a light emitting display device according to one or more aspects of the present disclosure, the seventh light emitting portion can be located at a center of the second area, and the fourth light emitting portion, the fifth light emitting portion, and the sixth light emitting portion surround the seventh light emitting portion.

In a light emitting display device according to one or more aspects of the present disclosure, the fourth light emitting portion can be closer than the first light emitting portion with respect to the seventh light emitting portion. The fifth light emitting portion can be closer than the second light emitting portion with respect to the seventh light emitting portion. The sixth light emitting portion can be than the third light emitting portion closer with respect to the seventh light emitting portion.

In a light emitting display device according to one or more aspects of the present disclosure, each of the first to seventh light emitting portions can comprise a first electrode and a second electrode opposite each other, the plurality of stacks including at least a first stack and a second stack between the first electrode and the second electrode, and a charge generation layer between the first stack and the second stack. Each of the first and second stacks can comprise a first common layer, a light emitting layer, and a second common layer.

In a light emitting display device according to one or more aspects of the present disclosure, the light emitting layer can comprise a first color light emitting layer to emit the first color of light within each of the first stack and the second stack at the first light emitting portion and the fourth light emitting portion, a second color light emitting layer to emit the second color of light within each of the first stack and the second stack at the second light emitting portion and the fifth light emitting portion; and a third color light emitting layer to emit the third color of light within each of the first stack and the second stack at the third light emitting portion and the sixth light emitting portion.

In a light emitting display device according to one or more aspects of the present disclosure, the second color light emitting layer and the third color light emitting layer can be in contact with each other at the seventh light emitting portion. The second color light emitting layer and the first color light emitting layer can overlap each other, and interpose the charge generation layer therebetween.

In a light emitting display device according to one or more aspects of the present disclosure, at the seventh light emitting portion, the second color light emitting layer can be in contact with the first common layer of the first stack, the third color light emitting layer can be in contact with the second common layer of the first stack. The first color light emitting layer can be located between the first common layer and the second common layer of the second stack.

In a light emitting display device according to one or more aspects of the present disclosure, at the seventh light emitting portion, the first color light emitting layer can be located between the first common layer and the second common layer of the first stack. The second color light emitting layer can be in contact with the first common layer of the second stack, and the third color light emitting layer can be in contact with the second common layer of the second stack.

In a light emitting display device according to one or more aspects of the present disclosure, the seventh light emitting portion can have a largest vertical distance between the first electrode and the second electrode, among the first to seventh light emitting portions.

In a light emitting display device according to one or more aspects of the present disclosure, the first light emitting portion and the fourth light emitting portion can be disposed side by side. The second light emitting portion and the fifth light emitting portion can be disposed side by side. The third light emitting portion and the sixth light emitting portion can be disposed side by side.

In a light emitting display device according to one or more aspects of the present disclosure, the second light emitting portion can be disposed to have a different axis from at least one of the first light emitting portion and the third light emitting portion.

In a light emitting display device according to one or more aspects of the present disclosure, the first area and the second area can face each other.

In a light emitting display device according to one or more aspects of the present disclosure, the first color of light can have an emission peak at a wavelength of 410 nm to 490 nm. The second color of light can have an emission peak at a wavelength of 510 nm to 590 nm. The third color of light can have an emission peak at a wavelength of 600 nm to 650 nm.

In a light emitting display device according to one or more aspects of the present disclosure, each of the first to seventh light emitting portions can comprise a first electrode and a second electrode opposite each other and a first stack, a charge generation layer, and a second stack sequentially between the first electrode and the second electrode. The first stack can comprise a first common layer and a second common layer, and the second stack can comprise a third common layer and a fourth common layer. Between the first common layer and the second common layer, the first light emitting portion, the fourth light emitting portion, and the seventh light emitting portion can comprise a first blue light emitting layer, the second light emitting portion and the fifth light emitting portion can comprise a first green light emitting layer, and the third light emitting portion and the sixth light emitting portion can comprise a first red light emitting layer. Between the third common layer and the fourth common layer, the first light emitting portion and the fourth light emitting portion can comprise a second blue light emitting layer, the second light emitting portion, the fifth light emitting portion and the seventh light emitting portion can comprise a second green light emitting layer, and the third light emitting portion and the sixth light emitting portion can comprise a second red light emitting layer.

In a light emitting display device according to one or more aspects of the present disclosure, the second green light emitting layer and the second red light emitting layer can be in contact each other at the seventh light emitting portion.

A light emitting display device according to one or more aspects of the present disclosure can further comprise a bank between the first to seventh light emitting portions.

In a light emitting display device according to one or more aspects of the present disclosure, the first blue light emitting layer can overlap with the seventh light emitting portion, the first light emitting portion, the fourth light emitting portion, and the bank between the seventh light emitting portion, the first light emitting portion, and the fourth light emitting portion. The second green light emitting layer can overlap with the seventh light emitting portion, the second light emitting portion, the fifth light emitting portion, and the bank between the seventh light emitting portion, the second light emitting portion, and the fifth light emitting portion. The second red light emitting layer can overlap with the seventh light emitting portion, the third light emitting portion, the sixth light emitting portion, and the bank between the seventh light emitting portion, the third light emitting portion, and the sixth light emitting portion.

In a light emitting display device according to one or more aspects of the present disclosure, the first electrode of each of the first to seventh light emitting portions can be independently connected to a corresponding thin film transistor.

A light emitting display device according to one or more aspects of the present disclosure can comprise a blue light emitting portion, a green light emitting portion, a red light emitting portion, and a white light emitting portion on a substrate, each of which comprises a first electrode and a second electrode opposite each other and a charge generation layer between the first electrode and the second electrode, a first blue light emitting layer and a second blue light emitting layer overlapping each other at the blue light emitting portion, a first green light emitting layer and a second green light emitting layer overlapping each other at the green light emitting portion; and a first red light emitting layer and a second red light emitting layer overlapping each other at the red light emitting portion. At the white light emitting portion, the first blue light emitting layer can overlap with the second green light emitting layer and the second red light emitting layer. The charge generation layer can be positioned between the first blue light emitting layer and at least one of the second green light emitting layer or the second red light emitting layer.

In a light emitting display device according to one or more aspects of the present disclosure, each of the blue light emitting portion, the green light emitting portion, and the red light emitting portion can comprise a first area adjacent to the white light emitting portion and a second area spaced more apart than the first area with respect to the white light emitting portion. A bank can be provided between the first area and the second area.

In a light emitting display device according to one or more aspects of the present disclosure, each of the white light emitting portion and the first area and the second area of the blue light emitting portion, the green light emitting portion, and the red light emitting portion can be independently connected to a thin film transistor.

A light emitting display device according to one or more aspects of the present disclosure can comprise a blue light emitting portion, a green light emitting portion, a red light emitting portion, and a white light emitting portion on a substrate, each of which comprises a first electrode and a second electrode opposite each other and a charge generation layer between the first electrode and the second electrode, a first blue light emitting layer and a second blue light emitting layer interposing the charge generation layer therebetween at the blue light emitting portion, a first green light emitting layer and a second green light emitting layer interposing the charge generation layer therebetween at the green light emitting portion and a first red light emitting layer and a second red light emitting layer interposing the charge generation layer therebetween at the red light emitting portion. The first blue light emitting layer can overlap with the second green light emitting layer and the second red light emitting layer at the white light emitting portion.

In a light emitting display device according to one or more aspects of the present disclosure, each of the blue light emitting portion, the green light emitting portion, and the red light emitting portion can comprise a first area adjacent to the white light emitting portion and a second area spaced more apart than the first area with respect to the white light emitting portion.

In a light emitting display device according to one or more aspects of the present disclosure, each of the blue light emitting portion, the green light emitting portion, and the red light emitting portion can be independently turned on and turned off.

In a light emitting display device according to one or more aspects of the present disclosure, a bank can be provided between the first area and the second area.

As is apparent from the above description, a light emitting display device according to the present disclosure has the following effects.

First, each of first, second and third light emitting portions is configured such that color light emitting layers configured to emit the same color of light overlap with each other, whereby it is possible to improve color purity. In addition, a white light emitting portion is located in an area surrounded by the first, second and third light emitting portions, which emit different colors of light. In this situation, the white light emitting portion is provided separately from the color light emitting portions, whereby it is possible to extend white expression and to improve white efficiency of the light emitting display device.

Second, a light emitting layer of the white light emitting portion is formed in the same process as a process of forming a light emitting layer in one stack of each of the first to third light emitting portions. Consequently, it is possible to provide the white light emitting portion without an additional deposition mask, and therefore it is possible to simplify the process.

Third, the color light emitting layer is shared by the color light emitting portions and the white light emitting portion, whereby it is possible to implement high resolution without reducing the area of the aperture of the mask used to form the color light emitting layer. It is possible to provide a white light emitting portion having a size equivalent to ½ or ⅓ of the area of the aperture of the deposition mask, whereby it is possible to implement high resolution without development or change of equipment (e.g., a deposition mask having a larger aperture can still be used to make a smaller light emitting portion).

Fourth, the area of the material used to form the color light emitting layer extends to the white light emitting portion from another light emitting portion, not the single color light emitting portion, whereby it is possible to increase the effective deposition area of the material of the color light emitting layer and to increase material utilization rate, and therefore it is possible to achieve environmental improvement and conserve resources.

Fifth, in the light emitting display device according to an embodiment of the present disclosure, the bank area is increased in the high-resolution structure, whereby it is possible to increase resistance to lateral current leakage as the result of the increase in the area of the bank between adjacent subpixels, and therefore it is possible to prevent low-gradation color leakage due to lateral current leakage.

While the embodiments of the present disclosure have been described with reference to the accompanying drawings, the present disclosure is not limited to the embodiments and can be embodied in various different forms, and those skilled in the art will appreciate that the present disclosure can be embodied in specific forms other than those set forth herein without departing from the technical idea and essential characteristics of the present disclosure. The disclosed embodiments are therefore to be construed in all aspects as illustrative and not restrictive.

What is claimed is:

1. A light emitting display device comprising:
a first area on a substrate, the first area including a first light emitting portion configured to emit a first color of light, a second light emitting portion configured to emit a second color of light, and a third light emitting portion configured to emit a third color of light; and
a second area adjacent to the first area on the substrate, the second area including a fourth light emitting portion configured to emit the first color of light, a fifth light emitting portion configured to emit the second color of light, a sixth light emitting portion configured to emit the third color of light, and a seventh light emitting portion configured to emit white light,
wherein each of the first, second, third, fourth, fifth, sixth and seventh light emitting portions includes a plurality of stacks, and
wherein a light emitting layer in at least one of the plurality of stacks among the fourth, fifth and sixth light emitting portions is continuous and extends into the seventh light emitting portion.

2. The light emitting display device according to claim 1, wherein the seventh light emitting portion is located at a center of the second area, and
wherein the fourth light emitting portion, the fifth light emitting portion and the sixth light emitting portion surround the seventh light emitting portion.

3. The light emitting display device according to claim 2, wherein:
the fourth light emitting portion is disposed closer to the seventh light emitting portion than the first light emitting portion with respect to the seventh light emitting portion,
the fifth light emitting portion is disposed closer to the seventh light emitting portion than the second light emitting portion with respect to the seventh light emitting portion, and
the sixth light emitting portion is disposed closer to the seventh light emitting portion than the third light emitting portion with respect to the seventh light emitting portion.

4. The light emitting display device according to claim 1, wherein each of the first, second, third, fourth, fifth, sixth and seventh light emitting portions includes:
a first electrode and a second electrode disposed opposite each other;
a first stack and a second stack included in the plurality of stacks, the first and second stacks being disposed between the first electrode and the second electrode; and
a charge generation layer between the first stack and the second stack,
wherein each of the first and second stacks includes a first common layer, a light emitting layer, and a second common layer.

5. The light emitting display device according to claim 4, wherein the light emitting layer includes:
a first color light emitting layer configured to emit the first color of light within each of the first stack and the second stack at the first light emitting portion and the fourth light emitting portion;
a second color light emitting layer configured to emit the second color of light within each of the first stack and the second stack at the second light emitting portion and the fifth light emitting portion; and
a third color light emitting layer configured to emit the third color of light within each of the first stack and the second stack at the third light emitting portion and the sixth light emitting portion.

6. The light emitting display device according to claim 5, wherein:
the second color light emitting layer and the third color light emitting layer are in contact with each other at the seventh light emitting portion, and
the second color light emitting layer and the first color light emitting layer overlap with each other, and the charge generation layer is interposed therebetween.

7. The light emitting display device according to claim 6, wherein at the seventh light emitting portion, the second color light emitting layer is in contact with the first common layer of the first stack, the third color light emitting layer is in contact with the second common layer of the first stack, and the first color light emitting layer is located between the first common layer and the second common layer of the second stack.

8. The light emitting display device according to claim 6, wherein at the seventh light emitting portion, the first color light emitting layer is located between the first common layer and the second common layer of the first stack, the second color light emitting layer is in contact with the first common layer of the second stack, and the third color light emitting layer is in contact with the second common layer of the second stack.

9. The light emitting display device according to claim 5, wherein a vertical distance between the first electrode and the second electrode in the seventh light emitting portion is larger than a vertical distance between the first electrode and the second electrode in each of the first, second, third, fourth, fifth, sixth and seventh light emitting portions.

10. The light emitting display device according to claim 1, wherein:
the first light emitting portion is disposed adjacent to the fourth light emitting portion,
the second light emitting portion is disposed adjacent to the fifth light emitting portion, and
the third light emitting portion is disposed adjacent to the sixth light emitting portion,
wherein the second light emitting portion is disposed along a different axis than at least one of the first light emitting portion and the third light emitting portion.

11. The light emitting display device according to claim 1, wherein the first area and the second area face each other.

12. The light emitting display device according to claim 1, wherein:
the first color of light has an emission peak at a wavelength of about 410 nm to 490 nm,
the second color of light has an emission peak at a wavelength of about 510 nm to 590 nm, and
the third color of light has an emission peak at a wavelength of about 600 nm to 650 nm.

13. The light emitting display device according to claim 1, wherein each of the first, second, third, fourth, fifth, sixth and seventh light emitting portions includes:
a first electrode and a second electrode disposed opposite each other; and
a first stack, a charge generation layer and a second stack sequentially disposed between the first electrode and the second electrode,
wherein the first stack includes a first common layer and a second common layer,
wherein the second stack includes a third common layer and a fourth common layer,
wherein each of the first light emitting portion, the fourth light emitting portion, and the seventh light emitting portion includes a first blue light emitting layer disposed between the first common layer and the second common layer in the first stack,
wherein each of the second light emitting portion and the fifth light emitting portion includes a first green light emitting layer disposed between the first common layer and the second common layer in the first stack,
wherein each of the third light emitting portion and the sixth light emitting portion includes a first red light emitting layer disposed between the first common layer and the second common layer,
wherein each of the first light emitting portion and the fourth light emitting portion includes a second blue light emitting layer disposed between the third common layer and the fourth common layer in the second stack,
wherein each of the second light emitting portion, the fifth light emitting portion and the seventh light emitting portion includes a second green light emitting layer disposed between the third common layer and the fourth common layer in the second stack,
wherein each of the third light emitting portion and the sixth light emitting portion includes a second red light emitting layer disposed between the third common layer and the fourth common layer in the second stack, and
wherein the second green light emitting layer and the second red light emitting layer are in contact with each other at the seventh light emitting portion.

14. The light emitting display device according to claim 13, further comprising:
a bank disposed between the first, second, third, fourth, fifth, sixth and seventh light emitting portions, the first electrode of each of the first to seventh light emitting portions being independently connected to a thin film transistor.

15. The light emitting display device according to claim 14, wherein the first blue light emitting layer extends across the seventh light emitting portion, the first light emitting portion, the fourth light emitting portion and a portion of the bank between the seventh light emitting portion, the first light emitting portion and the fourth light emitting portion,
wherein the second green light emitting layer extends across the seventh light emitting portion, the second light emitting portion, the fifth light emitting portion and a portion of the bank between the seventh light emitting portion, the second light emitting portion and the fifth light emitting portion, and
wherein the second red light emitting layer extends across the seventh light emitting portion, the third light emitting portion, the sixth light emitting portion and a portion of the bank between the seventh light emitting portion, the third light emitting portion and the sixth light emitting portion.

16. A light emitting display device comprising:
a blue light emitting portion, a green light emitting portion, a red light emitting portion, and a white light emitting portion disposed on a substrate, each of the blue, green, red and white light emitting portions including a first electrode and a second electrode disposed opposite to each other and a charge generation layer disposed between the first electrode and the second electrode;
a first blue light emitting layer and a second blue light emitting layer overlapping with each other at the blue light emitting portion;
a first green light emitting layer and a second green light emitting layer overlapping with each other at the green light emitting portion; and
a first red light emitting layer and a second red light emitting layer overlapping with each other at the red light emitting portion,
wherein the first blue light emitting layer overlaps with both of the second green light emitting layer and the second red light emitting layer at the white light emitting portion, and
wherein the charge generation layer is disposed between the first blue light emitting layer and at least one of the second green light emitting layer or the second red light emitting layer at the white light emitting portion.

17. The light emitting display device according to claim 16, wherein:
each of the blue light emitting portion, the green light emitting portion, and the red light emitting portion includes a first area adjacent to the white light emitting portion and a second area spaced farther away from the white light emitting portion than the first area,
a bank is disposed between the first area and the second area of each of the blue light emitting portion, the green light emitting portion, and the red light emitting portion, and
each of the white light emitting portion, the first area of the blue light emitting portion, the second area of the blue light emitting portion, the first area of the green light emitting portion, the second area of the green light emitting portion, the first area of the red light emitting portion and the second area of the red light emitting portion is independently connected to a corresponding thin film transistor among a group of seven thin film transistors.

18. A light emitting display device comprising:
a blue light emitting portion, a green light emitting portion, a red light emitting portion, and a white light emitting portion disposed on a substrate, each of the blue, green, red and white light emitting portions including a first electrode and a second electrode disposed opposite to each other and a charge generation layer disposed between the first electrode and the second electrode;
a first blue light emitting layer, a second blue light emitting layer and a portion of the charge generation layer disposed between the first and second blue light emitting layers at the blue light emitting portion;
a first green light emitting layer, a second green light emitting layer and a portion of the charge generation layer disposed between the first and second green light emitting layers at the green light emitting portion; and
a first red light emitting layer, a second red light emitting layer and a portion of the charge generation layer disposed between the first and second red light emitting layers at the red light emitting portion,
wherein the first blue light emitting layer overlaps with both of the second green light emitting layer and the second red light emitting layer at the white light emitting portion.

19. The light emitting display device according to claim 18, wherein each of the blue light emitting portion, the green light emitting portion, and the red light emitting portion includes a first area disposed adjacent to the white light emitting portion and a second area spaced farther away from the white light emitting portion than the first area,
wherein a bank is disposed between the first area and the second area of each of the blue light emitting portion, the green light emitting portion, and the red light emitting portion, and
wherein each of the blue light emitting portion, the green light emitting portion, and the red light emitting portion is configured to be independently turned on and turned off.

20. A light emitting display device comprising:
a first stack having a first plurality of layers disposed on a substrate;
a second stack having a second plurality of layers disposed on the substrate;
a first subpixel disposed on the substrate, and configured to emit light of a first color; and
a second subpixel disposed on the substrate, and configured to emit light of a second color,
wherein each of the first subpixel and the second subpixel includes part of a light emitting layer in the first stack and part of a light emitting layer in the second stack, and
wherein the first subpixel is disposed adjacent to the second subpixel, and at least one of the light emitting layer in the first stack or the light emitting layer in the second stack extends across both of the first subpixel and the second subpixel.
